(19) United States
(12) Patent Application Publication
(10) Pub. No.: US 2025/0133841 A1
(43) Pub. Date: Apr. 24, 2025

(54) IMAGE SENSOR INCLUDING GROUND REGION

(71) Applicant: SAMSUNG ELECTRONICS CO., LTD., Suwon-si (KR)

(72) Inventors: MASATO FUJITA, Suwon-si (KR); Seungki Jung, Suwon-si (KR)

(73) Assignee: SAMSUNG ELECTRONICS CO., LTD., Suwon-si (KR)

(21) Appl. No.: 18/738,595

(22) Filed: Jun. 10, 2024

(30) Foreign Application Priority Data
Oct. 24, 2023 (KR) 10-2023-0142621

(51) Int. Cl. H01L 27/146

(52) U.S. Cl. CPC H10F 39/802; H10F 39/182; H10F 39/8053; H10F 39/8063; H10F 39/807; H10F 39/811

(57) ABSTRACT

An image sensor is provided. The image sensor includes: a substrate that includes a plurality of pixels, each of which includes a left sub-pixel and a right sub-pixel; a well region in the substrate on each of the plurality of pixels, the well region connecting the left sub-pixel and the right sub-pixel to each other; a pixel separation part that separates the plurality of pixels from each other and extends in the substrate between the left sub-pixel and the right sub-pixel; a left transfer transistor and a first logic transistor on the left sub-pixel; a right transfer transistor and a second logic transistor on the right sub-pixel; and a ground region in the substrate on one of the left sub-pixel and the right sub-pixel, and in contact with the well region. The ground region is adjacent to a corner of each of the plurality of pixels.

### CROSS-REFERENCE TO RELATED APPLICATION

This application claims priority to Korean Patent Application No. 10-2023-0142621 filed on Oct. 24, 2023, in the Korean Intellectual Property Office, the disclosure of which is incorporated by reference herein in its entirety.

### BACKGROUND

The present disclosure relates to an image sensor, and more particularly, to an image sensor including a ground region.

An image sensor is a semiconductor device to transforms optical images into electrical signals. The image sensor may be classified into a charge coupled device (CCD) type and a complementary metal oxide semiconductor (CMOS) type. The CMOS type image sensor may be referred to as a CMOS image sensor (CIS). The CIS may include a plurality of two-dimensionally arranged pixels. Each of the pixels includes a photodiode (PD). The photodiode serves to transform an incident light into an electrical signal.

### SUMMARY

One or more embodiments provide an image sensor capable of accomplishing sharp image quality.

According to an aspect of an embodiment, an image sensor includes: a substrate that includes a plurality of pixels, each of which includes a left sub-pixel and a right sub-pixel; a well region in the substrate on each of the plurality of pixels, the well region connecting the left sub-pixel and the right sub-pixel to each other; a pixel separation part that separates the plurality of pixels from each other and extends in the substrate between the left sub-pixel and the right sub-pixel; a left transfer transistor and a first logic transistor on the left sub-pixel; a right transfer transistor and a second logic transistor on the right sub-pixel; and a ground region in the substrate on one of the left sub-pixel and the right sub-pixel, and in contact with the well region. The ground region is adjacent to a corner of each of the plurality of pixels.

According to an aspect of an embodiment, an image sensor, including: a substrate including a plurality of pixel groups, each of which includes a plurality of pixels in a 2×2 arrangement, each of the plurality of pixels including a left sub-pixel and a right sub-pixel; a well region in the substrate on each of the plurality of pixels, the well region connecting the left sub-pixel and the right sub-pixel to each other; a pixel separation part that separates the plurality of pixels from each other and extends in the substrate between the left sub-pixel and the right sub-pixel; a left transfer transistor and a left active region on the left sub-pixel; a right transfer transistor and a right active region on the right sub-pixel; a ground region in the substrate on one of the left sub-pixel and the right sub-pixel, and in contact with the well region; and a ground line that extends over the substrate between the plurality of pixel groups. On each of the plurality of pixels, the ground region is adjacent to the ground line.

According to an aspect of an embodiment, an image sensor, including: a substrate having a first surface and a second surface that are opposite to each other, the substrate including a plurality of pixel groups, each of which including a plurality of pixels arranged in a 2×2 matrix, and each of the plurality of pixels including a left sub-pixel and a right sub-pixel; a first color filter on the first surface covering one of the plurality of pixel groups; a second color filter on the first surface covering another of the plurality of pixel groups; a third color filter on the first surface covering still another of the plurality of pixel groups; a plurality of microlenses respectively provided on the first color filter, the second color filter, and the third color filter and covering each of the plurality of pixels; a well region in the substrate on each of the plurality of pixels, the well region connecting the left sub-pixel and the right sub-pixel to each other; a pixel separation part that separates the plurality of pixels from each other and extends between the left sub-pixel and the right sub-pixel; a device isolation part adjacent to the second surface in the substrate, the device isolation part separating a left active region on the left sub-pixel from a right active region on the right sub-pixel; a left photoelectric conversion region in the substrate on the left sub-pixel of each of the plurality of pixels; a right photoelectric conversion region in the substrate on the right sub-pixel of each of the plurality of pixels; a left transfer transistor on the second surface on the left sub-pixel of each of the plurality of pixels; a right transfer transistor on the second surface on the right sub-pixel of each of the plurality of pixels; and a ground region in the substrate on one of the left sub-pixel and the right sub-pixel and in contact with the well region. The ground region is provided in plural, and the plurality of ground regions are adjacent to a corner of each of the plurality of pixel groups.

### BRIEF DESCRIPTION OF DRAWINGS

The above and other aspects and features will be more apparent from the following description of embodiments, taken in conjunction with the accompanying drawings.

FIG. 1 illustrates a plan view showing an image sensor according to some embodiments.

FIGS. 2A and 2B illustrate cross-sectional views taken along line A-A′ of FIG. 1.

FIG. 3 illustrates a cross-sectional view taken along line B-B′ of FIG. 1.

FIG. 4 illustrates a plan view showing pixel groups in an image sensor according to some embodiments.

FIG. 5 illustrates a plan view showing one pixel group in an image sensor according to some embodiments.

FIG. 6 illustrates a plan view showing a connection relationship between transistors and an arrangement of a pixel group of FIG. 5.

FIG. 7 illustrates an enlarged view showing section P1 of FIG. 6.

FIG. 8 illustrates a circuit diagram of an image sensor shown in FIG. 6.

FIG. 9 illustrates an enlarged view showing section P2 of FIG. 6.

FIG. 10 illustrates a cross-sectional view taken along line C-C′ of FIG. 9.

FIG. 11 illustrates an enlarged view showing section P2 of FIG. 6.

FIG. 12 illustrates a cross-sectional view taken along line C-C′ of FIG. 11.

FIG. 13 illustrates an enlarged view showing section P2 of FIG. 6.

FIG. 14 illustrates a cross-sectional view taken along line D-D′ of FIG. 13.

FIG. 15 illustrates a plan view showing one pixel group in an image sensor according to some embodiments.

FIG. 16 illustrates a plan view showing a connection relationship between transistors and an arrangement of a pixel group of FIG. 15.

FIG. 17 illustrates a plan view showing one pixel group in an image sensor according to some embodiments.

FIG. 18 illustrates a plan view showing a connection relationship between transistors and an arrangement of a pixel group of FIG. 17.

FIG. 19 illustrates a cross-sectional view taken along line E-E′ of FIG. 18.

FIG. 20 illustrates a circuit diagram of an image sensor shown in FIG. 18.

FIG. 21 illustrates a plan view showing one pixel group in an image sensor according to some embodiments.

FIG. 22 illustrates a plan view showing a connection relationship between transistors and an arrangement of a pixel group of FIG. 21.

FIG. 23 illustrates a plan view showing one pixel group in an image sensor according to some embodiments.

FIG. 24 illustrates a plan view showing a connection relationship between transistors and an arrangement of a pixel group of FIG. 23.

FIG. 25 illustrates a circuit diagram of an image sensor shown in FIG. 24.

FIG. 26 illustrates a plan view showing one pixel group in an image sensor according to some embodiments.

FIG. 27 illustrates a plan view showing a connection relationship between transistors and an arrangement of a pixel group of FIG. 26.

FIG. 28 illustrates a circuit diagram of an image sensor shown in FIG. 27.

FIG. 29 illustrates a plan view showing one pixel group in an image sensor according to some embodiments.

FIG. 30 illustrates a plan view showing a connection relationship between transistors and an arrangement of a pixel group of FIG. 29.

FIG. 31 illustrates a plan view showing one pixel group in an image sensor according to some embodiments.

FIG. 32 illustrates a plan view showing a connection relationship between transistors and an arrangement of a pixel group of FIG. 31.

FIG. 33 illustrates a plan view showing one pixel group in an image sensor according to some embodiments.

FIG. 34 illustrates a plan view showing a connection relationship between transistors and an arrangement of a pixel group of FIG. 33.

FIG. 35 illustrates a cross-sectional view showing an image sensor according to some embodiments.

### DETAILED DESCRIPTION

Some embodiments will now be described in detail with reference to the accompanying drawings to aid in clearly explaining the present inventive concepts. In this description, such terms as “first” and “second” may be used to simply distinguish identical or similar components from each other, and the sequence of such terms may be changed in accordance with the order of mention. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

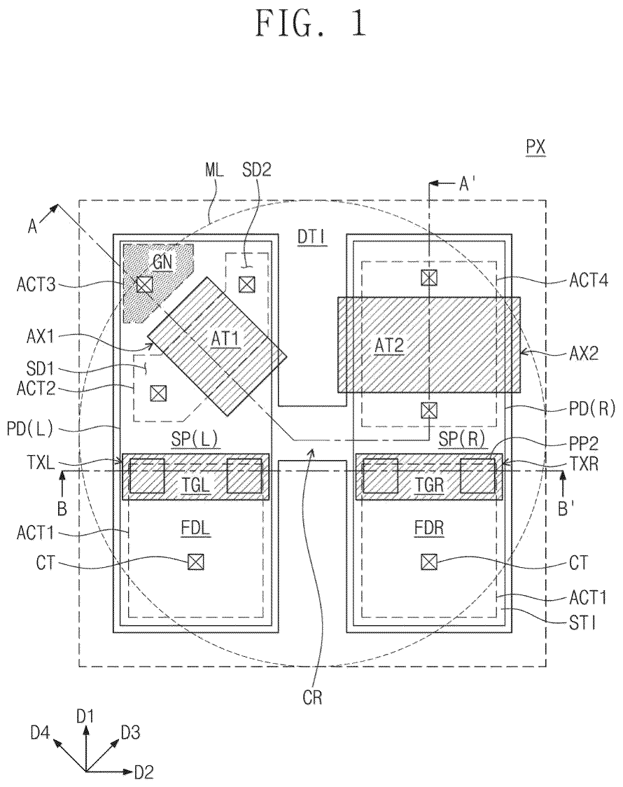

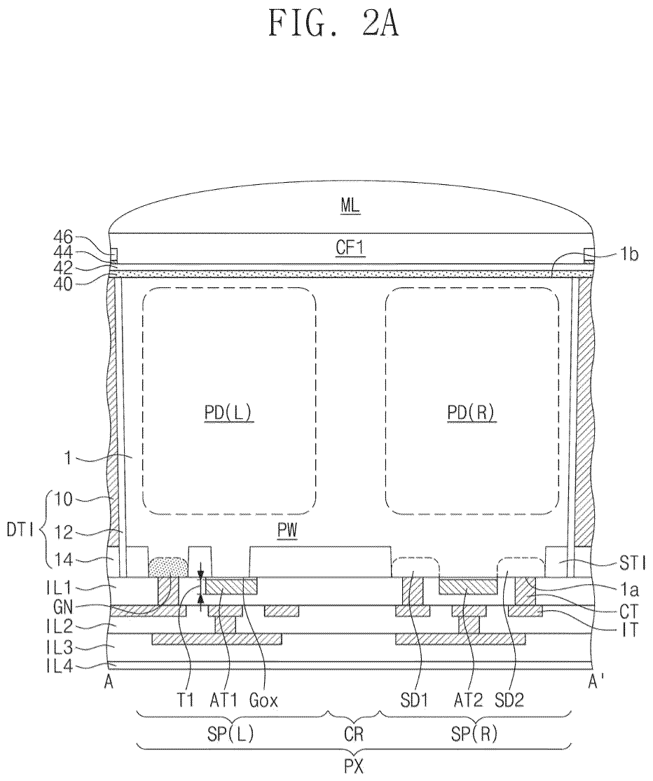

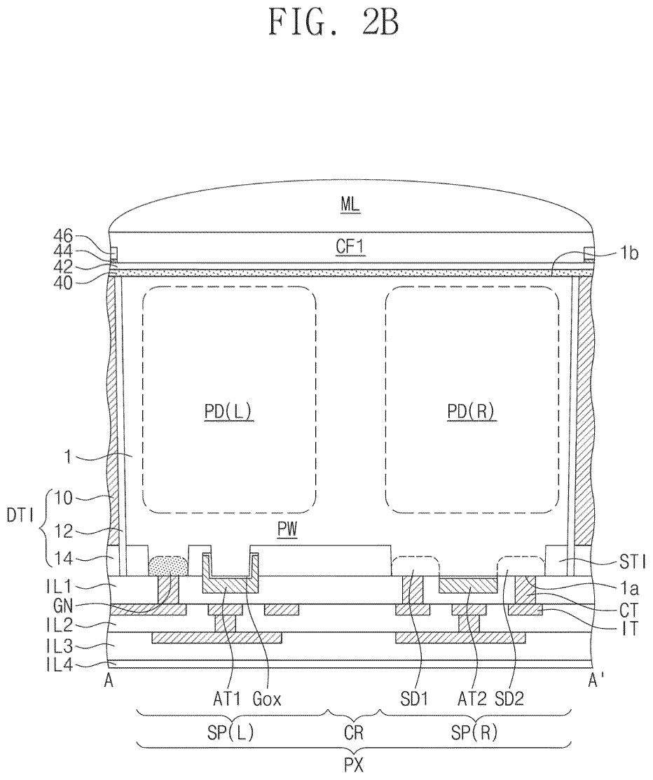

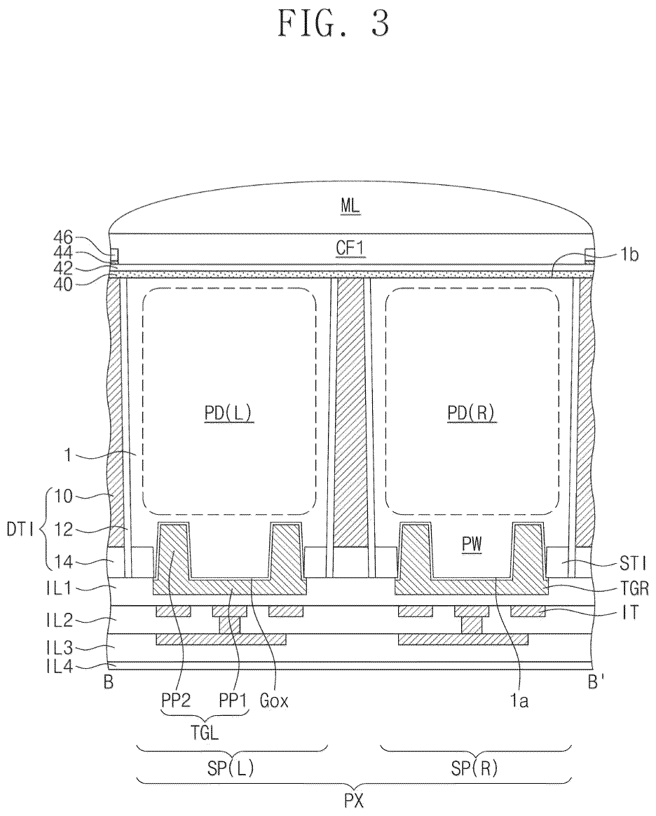

FIG. 1 illustrates a plan view showing an image sensor according to some embodiments. FIGS. 2A and 2B illustrate cross-sectional views taken along line A-A′ of FIG. 1. FIG. 3 illustrates a cross-sectional view taken along line B-B′ of FIG. 1.

Referring to FIGS. 1, 2A, 2B, and 3, a substrate 1 may be provided in an image sensor. The image sensor may have both an automatic focus function and an image sensor function. The substrate 1 may include a plurality of pixels PX that are two-dimensionally arranged along a first direction D1 and a second direction D2. FIG. 1 depicts by way of example one pixel PX. The substrate 1 may have a first surface 1a and a second surface 1b that are opposite to each other. The substrate 1 may receive light through the second surface 1b. For example, the substrate 1 may receive light that is incident on the second surface 1b. The substrate 1 may be either a single-crystalline wafer including silicon and/or germanium or a silicon-on-insulator (SOI) substrate. A well region PW may be formed in an entirety of the substrate 1. The well region PW may be doped with impurities having a first conductivity type. The first conductivity type may be of p-type. The impurities having the first conductivity type may be, for example, boron.

The substrate 1 may be provided therein with a pixel separation part DTI (i.e., a pixel separation portion) that separates and limits the pixels PX. The pixel separation part DTI may have a mesh shape when viewed in plan. The pixel separation part DTI may penetrate the substrate 1 to isolate the pixels PX from each other.

The pixel separation part DTI may include a separation conductive pattern 10, a separation dielectric pattern 12, and a capping dielectric pattern 14. The separation conductive pattern 10 may be spaced apart from the substrate 1. The separation conductive pattern 10 may include a conductive material having a refractive index different from that of the substrate 1. The separation conductive pattern 10 may include, for example, metal or polysilicon doped with impurities. The separation dielectric pattern 12 may include a dielectric material having a refractive index different from that of the substrate 1. The separation dielectric pattern 12 may be interposed between the separation conductive pattern 10 and the substrate 1. For example, the separation dielectric pattern 12 may include silicon oxide. The capping dielectric pattern 14 may be disposed below the separation conductive pattern 10. The capping dielectric pattern 14 may include, for example, at least one selected from silicon oxide, silicon nitride, and silicon oxynitride.

A negative bias voltage may be applied to the separation conductive pattern 10. The separation conductive pattern 10 may serve as a common bias line. Therefore, holes possibly present on a surface of the substrate 1 in contact with the pixel separation part DTI may be trapped to improve dark current properties.

One pixel PX may be divided into a left sub-pixel SP(L) and a right sub-pixel SP(R). The left sub-pixel SP(L) and the right sub-pixel SP(R) may be disposed side by side in the second direction D2. The second direction D2 may be parallel to the first surface 1a of the substrate 1. A portion of the pixel separation part DTI may be extend between the left sub-pixel SP(L) and the right sub-pixel SP(R). A cutting region CR may be provided between the left sub-pixel SP(L) and the right sub-pixel SP(R). On the cutting region CR, the pixel separation part DTI may be cut to disappear.

The pixel separation part DTI may isolate one pixel PX from a neighboring pixel PX. On one pixel PX, the left sub-pixel SP(L) and the right sub-pixel SP(R) may be connected to each other through the well region PW.

The substrate 1 may be provided therein with a device isolation part STI adjacent to the first surface 1a. The device isolation part STI may be formed by a shallow trench isolation method. The device isolation part STI may be formed to have a single-layered and multi-layered structure of at least one selected from a silicon oxide layer, a silicon nitride layer, and a silicon oxynitride layer. Alternatively, the device isolation part STI may be an impurity doping region. In this case, the device isolation part STI may be doped with impurities having the first conductivity type the same as that of the impurities doped in the well region PW

The device isolation part STI may separate active regions ACT1 to ACT4 on the first surface 1a. The left sub-pixel SP(L) may be provided with first to third active regions ACT1 to ACT3 that are disposed side by side along the first direction D1. The right sub-pixel SP(R) may be provided with first and fourth active regions ACT1 and ACT4 that are disposed side by side along the first direction D1. The first direction D1 may intersect the second direction D2. For example, the first direction D1 may be orthogonal to the second direction D2 and may be parallel to the first surface 1a of the substrate 1.

The first active region ACT1 disposed on the left sub-pixel SP(L) may occupy approximately half of an area of the left sub-pixel SP(L) depicted in FIG. 1, and the first active region ACT1 disposed on the right sub-pixel SP(R) may occupy approximately half of an area of the right sub-pixel SP(R) depicted in FIG. 1. The first active regions ACT1 may be disposed on the first sides of the left sub-pixel SP(L) and the right sub-pixel SP(R). The first active regions ACT1 may be provided with transfer transistors TXL and TXR. A left transfer transistor TXL may be disposed on the first active region ACT1 of the left sub-pixel SP(L). The left transfer transistor TXL may include a left transfer gate electrode TGL and a left floating diffusion region FDL adjacent to the left transfer gate electrode TGL. A right transfer transistor TXR may be disposed on the first active region ACT1 of the right sub-pixel SP(R). The right transfer transistor TXR may include a right transfer gate electrode TGR and a right floating diffusion region FDR adjacent to the right transfer gate electrode TGR. Each of the left floating diffusion region FDL and the right floating diffusion region FDR may be doped with impurities having a second conductivity type opposite to the first conductivity type. For example, the second conductivity type may be of n-type, and the impurities having the second conductivity type may be phosphorus or arsenic.

Each of the left transfer gate electrode TGL and the right transfer gate electrode TGR may include a primary part PP1 disposed on the first surface 1a of the substrate 1 and protruding parts PP2 that extend into the substrate 1. Each of the left and right transfer gate electrodes TGL and TGR may include two protruding parts PP2, but embodiments are not limited thereto. The number of the protruding part PP2 may be one or three or more. In some embodiments, each of the left and right transfer gate electrodes TGL and TGR may be a planar type without the protruding part PP2. A gate dielectric layer Gox may be interposed between the left transfer gate electrode TGL and the substrate 1, and between the right transfer gate electrode TGR and the substrate 1. The gate dielectric layer Gox may include a single layer or multiple layers of at least one selected from silicon oxide, metal oxide, silicon nitride, and silicon oxynitride.

The second active region ACT2 may have a shape elongated in a third direction D3. The third direction D3 may intersect the first direction D1 and the second direction D2 and may be parallel to the first surface 1a of the substrate 1. A first logic transistor AX1 may be disposed on the second active region ACT2. The second active region ACT2 may be called a left active region. A first logic gate electrode AT1 may extend in a fourth direction D4 across the second active region ACT2. The fourth direction D4 may intersect the first, second, and third directions D1, D2, and D3 and may be parallel to the first surface 1a of the substrate 1. The fourth direction D4 may intersect the third direction D3. On the second active region ACT2, first and second source/drain regions SD1 and SD2 may be disposed on opposite sides of the first logic gate electrode AT1. The first logic transistor AX1 may be constituted by the first logic gate electrode AT1 and the first and second source/drain regions SD1 and SD2 on opposite sides of the first logic gate electrode AT1.

A ground region GN may be disposed on the third active region ACT3. The ground region GN may be doped with impurities having the first conductivity type the same as that of the impurities of the well region PW, and may have an impurity concentration greater than that of the well region PW. The ground region GND may be in direct contact with the well region PW. The ground region GN may be adjacent to one of four corners of one pixel PX. As shown in FIG. 1, the ground region GN may be adjacent to a corner at a left upper end of the pixel PX.

The fourth active region ACT4 may have a shape elongated in the first direction D1. A second logic transistor AX2 may be disposed on the fourth active region ACT4. The fourth active region ACT4 may be called a right active region. A second logic gate electrode AT2 may extend in the second direction D2 across the fourth active region ACT4. On the fourth active region ACT4, first and second source/drain regions SD1 and SD2 may be disposed on opposite sides of the second logic gate electrode AT2. The first and second source/drain regions SD1 and SD2 may be doped with impurities having the second conductivity type. The second logic transistor AX2 may be constituted by the second logic gate electrode AT2 and the first and second source/drain regions SD1 and SD2 on opposite sides of the second logic gate electrode AT2.

A gate dielectric layer Gox may be interposed between the first logic gate electrode AT1 and the substrate 1. A gate dielectric layer Gox may be interposed between the second logic gate electrode AT2 and the substrate 1. The first logic gate electrode AT1 may have a planar type as shown in FIG. 2A. Alternatively, as shown in FIG. 2B, a portion of the first logic gate electrode AT1 may extend into the device isolation part STI to cover a lateral surface of the substrate 1. The second logic gate electrode AT2 may have the same shape as that of the first logic gate electrode AT1 of FIG. 2A or 2B. Each of the first logic transistor AX1 and the second logic transistor AX2 may independently be a reset transistor, a selection transistor, a source follower transistor, or a dummy transistor. The reset transistor may be called a dual conversion transistor.

On the left sub-pixel SP(L), a left photoelectric conversion region PD(L) may be disposed in the substrate 1. On the right sub-pixel SP(R), a right photoelectric conversion region PD(R) may be disposed in the substrate 1. The well region PW may be disposed between the left photoelectric conversion region PD(L) and the right photoelectric conversion region PD(R). On the cutting region CR, a device isolation part STI may be disposed on the first surface 1a of the substrate 1. The left photoelectric conversion region PD(L) and the right photoelectric conversion region PD(R) may be doped with impurities having the second conductivity type opposite to the first conductivity type. For example, the left photoelectric conversion region PD(L) and the right photoelectric conversion region PD(R) may be doped with n-type impurities such as phosphorus or arsenic. An n-type impurity region of each of the left and right photoelectric conversion regions PD(L) and PD(R) and a p-type impurity region of the well region PW therearound may form a PN junction, thereby constituting a photodiode. When light is incident thereon, the PN junction may generate electron-hole pairs.

The first surface 1a may be provided thereon with first, second, third, and fourth interlayer dielectric layers IL1, IL2, IL3, and IL4 that are sequentially stacked. Each of the first, second, third, and fourth interlayer dielectric layers IL1, IL2, IL3, and IL4 may have a single-layered or multi-layered structure of at least one selected from silicon oxide, silicon nitride, silicon oxynitride, and porous dielectrics.

The first interlayer dielectric layer IL1 may cover the gate electrodes TGL, TGR, AT1, and AT2. The first, second, and third interlayer dielectric layers IL1, IL2, and IL3 may have contacts CT therein. The first, second, third, and fourth interlayer dielectric layers IL1, IL2, IL3, and IL4 may have wiring lines IT therebetween.

A fixed charge layer 40 may be disposed on and in contact with the second surface 1b. The fixed charge layer 40 may be formed either of a metal oxide layer including oxygen whose amount is less than its stoichiometric ratio or of a metal fluoride layer including fluorine whose amount is less than its stoichiometric ratio. The fixed charge layer 40 may thus have a negative fixed charge. The fixed charge layer 40 may be formed of one of metal oxide and metal fluoride that include at least one metal selected from hafnium (Hf), zirconium (Zr), aluminum (Al), tantalum (Ta), titanium (Ti), yttrium (Y), and lanthanides. A hole accumulation may occur around the fixed charge layer 40. Therefore, dark current and white spot may be effectively reduced. For example, the fixed charge layer 40 may be one or both of an aluminum oxide layer and a hafnium oxide layer.

An antireflection layer 42 may be disposed on the fixed charge layer 40. The antireflection layer 42 may include, for example, silicon nitride. A light-shield grid pattern 44 and a low-refractive pattern 46 may be sequentially stacked on the antireflection layer 42. The light-shield grid pattern 44 and the low-refractive pattern 46 may have a mesh shape when viewed in plan and may overlap the pixel separation part DTI. The light-shield grid pattern 44 and the low-refractive pattern 46 may expose the antireflection layer 42. A first color filter CF1 may be disposed on the antireflection layer 42. A microlens ML may be disposed on the first color filter CF1. One microlens ML may cover one pixel PX.

The light-shield grid pattern 44 may include a material, such as titanium, which is not transparent to light. A sidewall of the low-refractive pattern 46 may be aligned with that of the light-shield grid pattern 44. The light-shield grid pattern 44 and the low-refractive pattern 46 may prevent crosstalk between neighboring pixels PX. The low-refractive pattern 46 may include an organic material. The low-refractive pattern 46 may have a refractive index less than that of the first color filter CF1. For example, the low-refractive pattern 46 may have a refractive index equal to or less than about 1.3.

The first color filter CF1 may include a photoresist material to which a dye or a pigment is added. The first color filter CF1 may have one of blue, red, and green colors. Alternatively, the first color filter CF1 may have one of cyan, yellow, and magenta colors.

The ground region GN may be disposed at a corner portion of the pixel PX. As the left sub-pixel SP(L) and the right sub-pixel SP(R) are connected to each other through the well region PW, the left sub-pixel SP(L) and the right sub-pixel SP(R) may all be electrically grounded even when the ground region GN is disposed on only one of the left sub-pixel SP(L) and the right sub-pixel SP(R).

The ground region GN is not disposed on the cutting region CR, and thus it may be possible to prevent a reduction in gate width of the second logic transistor AX2. An output of the second logic transistor AX2 may be increased and a random telegram signal (RTS) may be improved, and therefore the image sensor may achieve sharp image quality. In addition, as the ground region GN is not disposed on the cutting region CR, an autofocus (AF) segregation ratio may increase to perform an excellent autofocus function.

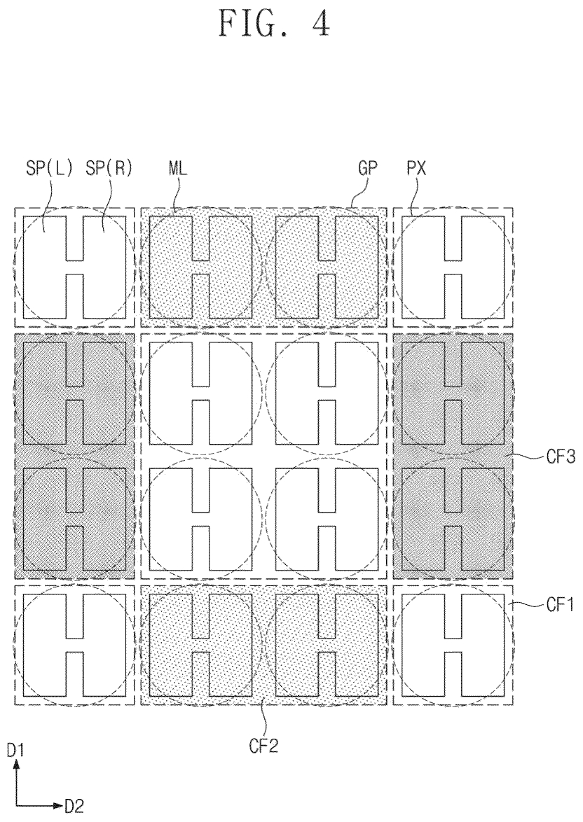

FIG. 4 illustrates a plan view showing pixel groups in an image sensor according to some embodiments.

Referring to FIG. 4, the substrate 1 may include a plurality of pixel groups GP. The pixel groups GP may be two-dimensionally arranged along the first direction D1 and the second direction D2. Each of the pixel groups GP may include the pixels PX arranged in a 2×2 matrix. Each of the pixels PX may include the left sub-pixel SP(L) and the right sub-pixel SP(R). Each of the pixels PX may have a structure depicted in FIGS. 1 to 3. The pixel separation part DTI may isolate the pixels PX from each other. The pixel separation part DTI may separate the pixel groups GP from each other. One of the pixel groups GP may be covered with the first color filter CF1. Another of the pixel groups GP may be covered with a second color filter CF2. Still another of the pixel groups GP may be covered with a third color filter CF3. The first to third color filters CF1 to CF3 may have different colors from each other. The color filters CF1 to CF3 may be disposed in a 2×2 Tetra pattern. A corner of each of the pixel groups GP may correspond to or adjoin that of each of the color filters CF1 to CF3.

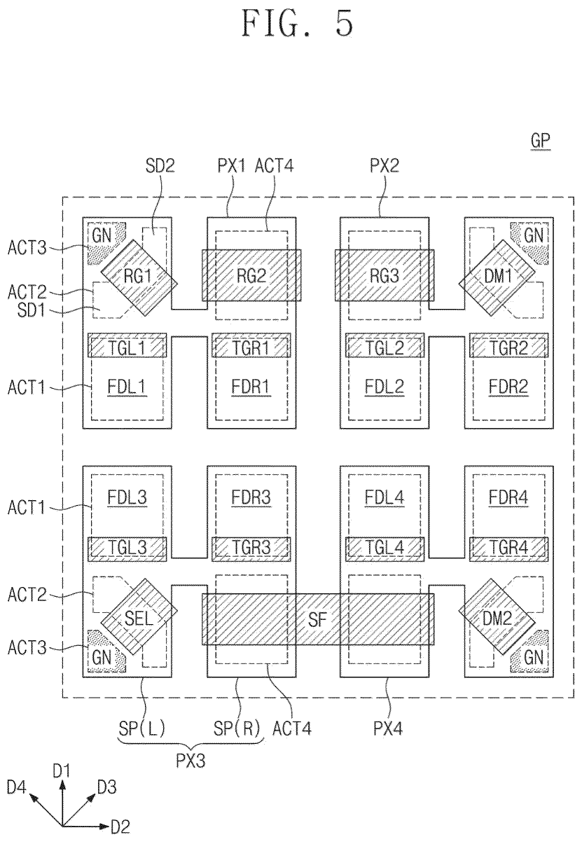

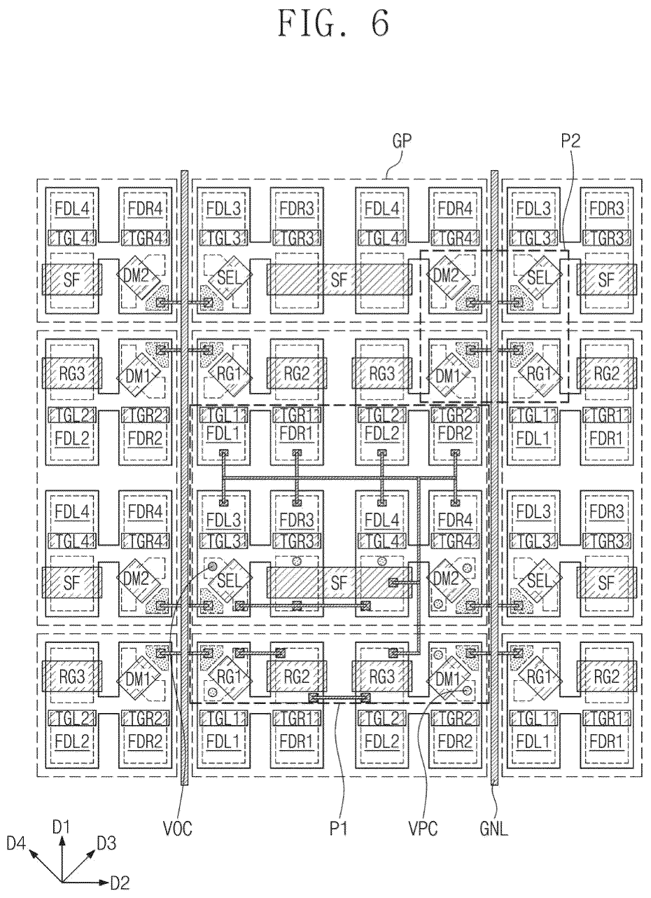

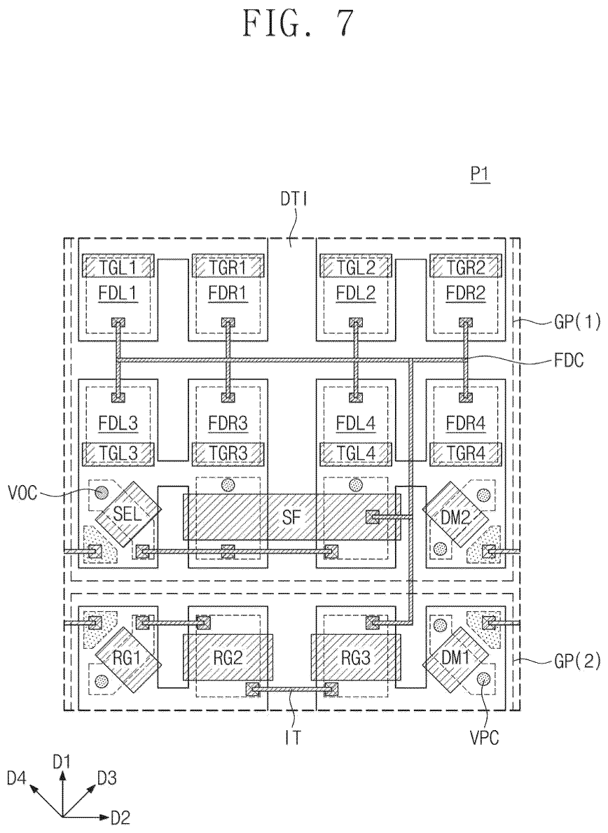

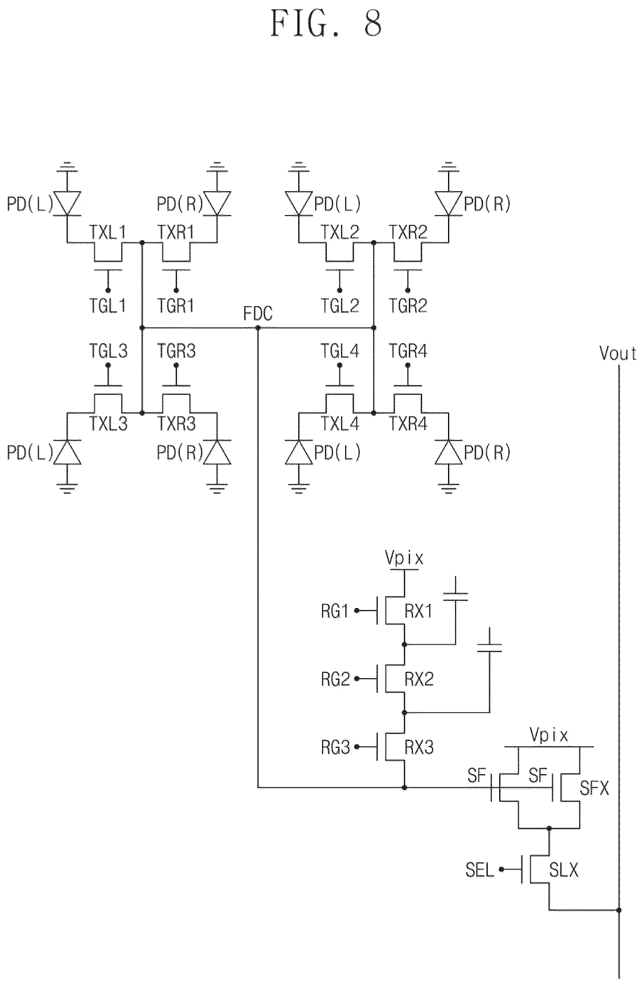

FIG. 5 illustrates a plan view showing one pixel group in an image sensor according to some embodiments. FIG. 6 illustrates a plan view showing a connection relationship between transistors and an arrangement of a pixel group of FIG. 5. FIG. 7 illustrates an enlarged view showing section P1 of FIG. 6. FIG. 8 illustrates a circuit diagram of an image sensor shown in FIG. 6.

Referring to FIGS. 5 to 8, one pixel group GP may include pixels PX1 to PX4 arranged in a 2×2 matrix. One pixel group GP may include first, second, third, and fourth pixels PX1, PX2, PX3, and PX4. The first and second pixels PX1 and PX2 may be arranged side by side in the second direction D2 to constitute a first row. The third and fourth pixels PX3 and PX4 may be arranged side by side in the second direction D2 to constitute a second row.

An arrangement of the active regions ACT1 to ACT4 disposed on the first and third pixels PX1 and PX3 may be mirror-symmetric to that of the active regions ACT1 to ACT4 disposed on the second and fourth pixels PX2 and PX4. For example, on the first and third pixels PX1 and PX3, the first to third active regions ACT1 to ACT3 may be disposed on the left sub-pixel SP(L), but on the second and fourth pixels PX2 and PX4, the first to third active regions ACT1 to ACT3 may be disposed on the right sub-pixel SP(R).

An arrangement of the active regions ACT1 to ACT4 disposed on the first and second pixels PX1 and PX2 may be symmetric to that of the active regions ACT1 to ACT4 disposed on the third and fourth pixels PX3 and PX4. For example, on the left sub-pixel SP(L) of each of the first and second pixels PX1 and PX2, the first to third active regions ACT1 to ACT3 may be disposed along the first direction D1. On the left sub-pixel SP(L) of each of the third and fourth pixels PX3 and PX4, the first to third active regions ACT1 to ACT3 may be disposed along a direction opposite to the first direction D1. On the first to fourth pixels PX1 to PX4, the ground region GN may be disposed in the third active region ACT3. When viewed in plan, on one pixel group GP, the ground regions GN may be correspondingly disposed adjacent to four corners of the one pixel group GP. As shown in FIG. 4, as one pixel group GP is covered with one of the color filters CF1, CF2, and CF3, when viewed in plan, the ground regions GN of one pixel group GP may be disposed adjacent to corners of one color filter.

Referring to FIG. 5, on the left sub-pixel SP(L) of the first pixel PX1, a first left floating diffusion region FDL1 and a first left transfer gate electrode TGL1 may be disposed on the first active region ACT1. The first left floating diffusion region FDL1 and the first left transfer gate electrode TGL1 may constitute a first left transfer transistor TXL1 of FIG. 8. A first reset gate electrode RG1 may extend in the fourth direction D4 across the second active region ACT2. The first reset gate electrode RG1, and first and second source/drain regions SD1 and SD2 disposed on opposite sides thereof, may constitute a first reset transistor RX1 of FIG. 8.

On the right sub-pixel SP(R) of the first pixel PX1, a first right floating diffusion region FDR1 and a first right transfer gate electrode TGR1 may be disposed on the first active region ACT1. The first right floating diffusion region FDR1 and the first right transfer gate electrode TGR1 may constitute a first right transfer transistor TXR1 of FIG. 8. A second reset gate electrode RG2 may extend in the second direction D2 across the fourth active region ACT4. The second reset gate electrode RG2, and first and second source/drain regions SD1 and SD2 disposed on opposite sides, thereof may constitute a second reset transistor RX2 of FIG. 8.

On the left sub-pixel SP(L) of the second pixel PX2, a second left floating diffusion region FDL2 and a second left transfer gate electrode TGL2 may be disposed on the first active region ACT1. The second left floating diffusion region FDL2 and the second left transfer gate electrode TGL2 may constitute a second left transfer transistor TXL2 of FIG. 8. A third reset gate electrode RG3 may extend in the second direction D2 across the fourth active region ACT4. The third reset gate electrode RG3, and first and second source/drain regions SD1 and SD2 disposed on opposite sides thereof, may constitute a third reset transistor RX3 of FIG. 8.

On the right sub-pixel SP(R) of the second pixel PX2, a second right floating diffusion region FDR2 and a second right transfer gate electrode TGR2 may be disposed on the first active region ACT1. The second right floating diffusion region FDR2 and the second right transfer gate electrode TGR2 may constitute a second right transfer transistor TXR2 of FIG. 8. A first dummy gate electrode DM1 may extend in the third direction D3 across the second active region ACT2. The first dummy gate electrode DM1, and first and second source/drain regions SD1 and SD2 disposed on opposite sides thereof, may constitute a first dummy transistor. A pixel voltage Vpix or a ground voltage may be applied through pixel contacts VPC to the first dummy gate electrode DM1 and the first and second source/drain regions SD1 and SD2 disposed on opposite sides of the first dummy gate electrode DM1.

On the left sub-pixel SP(L) of the third pixel PX3, a third left floating diffusion region FDL3 and a third left transfer gate electrode TGL3 may be disposed on the first active region ACT1. The third left floating diffusion region FDL3 and the third left transfer gate electrode TGL3 may constitute a third left transfer transistor TXL3 of FIG. 8. A selection gate electrode SEL may extend in the third direction D3 across the second active region ACT2. The selection gate electrode SEL, and first and second source/drain regions SD1 and SD2 disposed on opposite sides thereof, may constitute a selection transistor SLX of FIG. 8.

On the right sub-pixel SP(R) of the third pixel PX3, a third right floating diffusion region FDR3 and a third right transfer gate electrode TGR3 may be disposed on the first active region ACT1. The third right floating diffusion region FDR3 and the third right transfer gate electrode TGR3 may constitute a third right transfer transistor TXR3 of FIG. 8.

On the left sub-pixel SP(L) of the fourth pixel PX4, a fourth left floating diffusion region FDL4 and a fourth left transfer gate electrode TGL4 may be disposed on the first active region ACT1. The fourth left floating diffusion region FDL4 and the fourth left transfer gate electrode TGL4 may constitute a fourth left transfer transistor TXL4 of FIG. 8.

A source follower gate electrode SF may extend in the second direction D2 to extend across the fourth active region ACT4 of the right sub-pixel SP(R) of the third pixel PX3 and the fourth active region ACT4 of the left sub-pixel SP(L) of the fourth pixel PX4. The source follower gate electrode SF may extend in the second direction D2 across the pixel separation part DTI between the third pixel PX3 and the fourth pixel PX4. A width in the second direction D2 of the source follower gate electrode SF may be greater than that of the second reset gate electrode RG2 or the third reset gate electrode RG3. The source follower gate electrode SF, and first and second source/drain regions SD1 and SD2 disposed on opposite sides thereof, may constitute a source follower transistor SFX of FIG. 8. As the source follower transistor SFX extends across two fourth active regions ACT4 that are adjacent to each other, there may be a circuit structure the same as that in which two source follower transistors SFX are connected in parallel. This structure may constitute a fingered type source follower transistor SFX, which may reduce signal noise.

Among other transfer, reset, and selection transistors, a source follower transistor may be most sensitive to the effect of intrinsic noise of transistor, such as thermal noise and flicker noise. The noise at the source follower transistor may be transferred to an internal circuit, and thus image quality may deteriorate. As the source follower transistor SFX is formed in a fingered type, the effect of the intrinsic noise such as thermal noise and flicker noise of transistor may be decreased to reduce signal noise and to satisfactorily read an electrical potential of a floating diffusion (FD) connection line FDC.

On the right sub-pixel SP(R) of the fourth pixel PX4, a fourth right floating diffusion region FDR4 and a fourth right transfer gate electrode TGR4 may be disposed on the first active region ACT1. The fourth right floating diffusion region FDR4 and the fourth right transfer gate electrode TGR4 may constitute a fourth right transfer transistor TXR4 of FIG. 8. A second dummy gate electrode DM2 may extend in the fourth direction D4 across the second active region ACT2. The second dummy gate electrode DM2, and first and second source/drain regions SD1 and SD2 disposed on opposite sides thereof, may constitute a second dummy transistor. A pixel voltage Vpix or a ground voltage may be applied through pixel contacts VPC to the second dummy gate electrode DM2 and the first and second source/drain regions SD1 and SD2 disposed on opposite sides of the second dummy gate electrode DM2.

The dummy gate electrodes DM1 and DM2 may be formed to prevent failure of loading effect during the formation of gate electrodes. In addition, as the pixel voltage Vpix or the ground voltage is applied to all of the dummy gate electrodes DM1 and DM2 and the first and second source/drain regions SD1 and SD2 on opposite sides thereof, it may be possible to prevent or minimize signal noise of the wiring lines IT adjacent thereto.

Referring to FIGS. 6 to 8, the pixel group GP of FIG. 5 may be two-dimensionally arranged along the first and second directions D1 and D2. In some embodiments, the pixel groups GP of FIG. 5 may be arranged to achieve mirror-symmetry along the first and second directions D1 and D2.

The pixel groups GP may be provided with ground lines GNL therebetween. The ground lines GNL may extend along the first direction D1. The ground lines GNL may be connected to the ground regions GN through the contacts CT and the wiring lines IT.

The pixel groups GP may include a first pixel group GP(1) and a second pixel group GP(2) that are adjacent to each other in the first direction D1. Referring to FIGS. 4, 6, and 7, the first pixel group GP(1) may be covered with the first color filter CF1. The second pixel group GP(2) may be covered with the second color filter CF2. The first pixel group GP(1) may detect a first color light. The second pixel group GP(2) may detect a second color light.

The floating diffusion regions FDL1 to FDL4 and FDR1 to FDR4 disposed on the first pixel group GP(1) may all be connected to the FD connection line FDC, and the FD connection line FDC may be connected to the source follower gate electrode SF disposed on the first pixel group GP(1). As the floating diffusion regions FDL1 to FDL4 and FDR1 to FDR4 are disposed adjacent to each other, the FD connection line FDC may have a relatively short length and thus the image sensor may decrease in noise.

The FD connection line FDC may be connected to a source/drain region on one side of the third reset gate electrode RG3 of the second pixel group GP(2) that detects light whose color is different from that of light which the first pixel group GP(1) detects. This connection structure may cause the FD connection line FDC to have a relatively short length. There may be a reduction in parasitic capacitance between the FD connection line FDC and its adjacent wiring lines IT, and thus there may be a decrease in signal noise.

In accordance with an operating mode of the image sensor, the first to fourth left transfer transistors TXL1 to TXL4 and the first to fourth right transfer transistors TXR1 to TXR4 may be sequentially turned on, or some of the transfer transistors TXL1 to TXL4 and TXR1 to TXR4 may be selectively or simultaneously turned on.

The first to third reset transistors RX1 to RX3 may be connected in series through the wiring lines IT. The first to third reset transistors RX1 to RX3 may be interchangeably arranged. The number of the first to third reset transistors RX1 to RX3 that are turned on may be changed depending on illumination at which the image sensor operates. When the image sensor operates at high illumination, the first to third reset transistors RX1 to RX3 may all be turned on. Therefore, the image sensor may have an increased full well capacity (FWC). When the image sensor operates at low illumination, only one of the first to third reset transistors RX1 to RX3 may be turned on. At least one of the first to third reset transistors RX1 to RX3 may be called a dual conversion transistor.

On the first pixel group GP(1), one terminal (or source/drain region) of the source follower transistor SFX including the source follower gate electrode SF may be connected to one terminal (or source/drain region) of the selection transistor SLX including the selection gate electrode SEL. Another terminal (or source/drain region) of the selection transistor SLX may be connected through an output contact VOC to an output line Vout. The output contact VOC may be disposed adjacent to a ground line GNL, and thus the ground line GNL may serve as an electrical shield. Therefore, an output value through the output contact VOC may not be affected by a neighboring pixel group GP. Accordingly, the image sensor may accomplish sharp image quality.

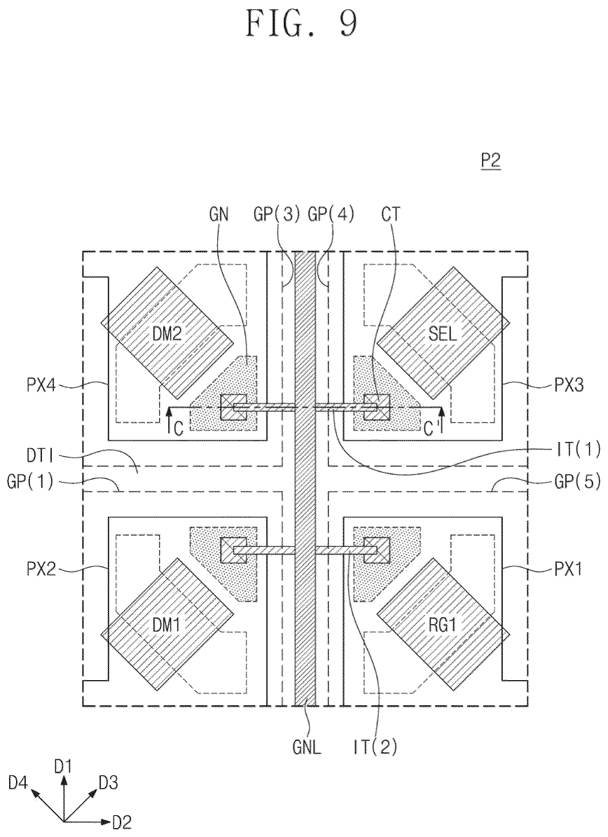

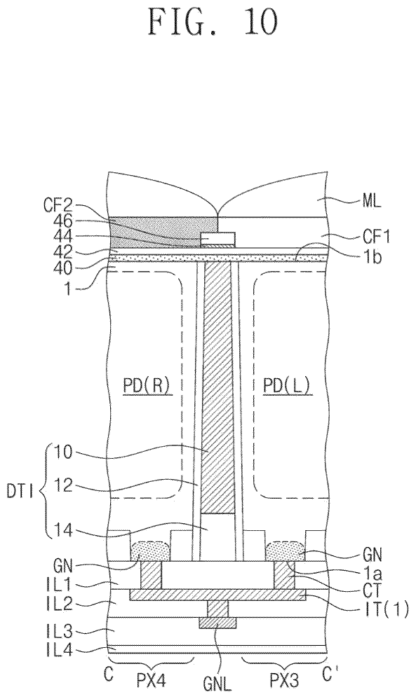

FIG. 9 illustrates an enlarged view showing section P2 of FIG. 6. FIG. 10

illustrates a cross-sectional view taken along line C-C′ of FIG. 9.

Referring to FIGS. 9 and 10, the pixel groups GP may include first, third, fourth, and fifth pixel groups GP(1), GP(3), GP(4), and GP(5) that are adjacent to each other along a clockwise direction. Referring to FIGS. 4, 6, and 9, the first pixel group GP(1) and the fourth pixel group GP(4) may be covered with the first color filter CF1. The third pixel group GP(3) may be covered with the second color filter CF2. The fifth pixel group GP(5) may be covered with the third color filter CF3. The first pixel group GP(1) and the fourth pixel group GP(4) may detect a first color light. The third pixel group GP(3) may detect a second color light. The fifth pixel group GP(5) may detect a third color light.

The ground line GNL may be disposed between the third and fourth pixel groups GP(3) and GP(4) and between the first and fifth pixel groups GP(1) and GP(5). The ground regions GN may aggregate toward a center between the first, third, fourth, and fifth pixel groups GP(1), GP(3), GP(4), and GP(5).

The ground regions GN of the first, third, fourth, and fifth pixel groups GP(1), GP(3), GP(4), and GP(5) may be adjacent to and spaced apart at the same distance from the ground line GNL. The ground regions GN may be connected to the ground line GNL through the contacts CT and the wiring lines IT. The second dummy gate electrode DM2 adjacent to the ground region GN may be disposed on the fourth pixel PX4 of the third pixel group GP(3). The first dummy gate electrode DM1 adjacent to the ground region GN may be disposed on the second pixel PX2 of the first pixel group GP(1). The selection gate electrode SEL adjacent to the ground region GN may be disposed on the third pixel PX3 of the fourth pixel group GP(4). The first reset gate electrode RG1 adjacent to the ground region GN may be disposed on the first pixel PX1 of the fifth pixel group GP(5).

The wiring lines IT may include a first wiring line IT(1) and a second wiring line IT(2). The first wiring line IT(1) may extend in the second direction D2 to connect the ground region GN of the fourth pixel PX4 in the third pixel group GP(3) to the ground region GN of the third pixel PX3 in the fourth pixel group GP(4). The second wiring line IT(2) may extend in the second direction D2 to connect the ground region GN of the second pixel PX2 in the first pixel group GP(1) to the ground region GN of the first pixel PX1 in the fifth pixel group GP(5). The first wiring line IT(1) and the second wiring line IT(2) may be spaced apart from each other in the first direction D1. The first wiring line IT(1) and the second wiring line IT(2) may be disposed between the first interlayer dielectric layer IL1 and the second interlayer dielectric layer IL2. The ground line GNL may be positioned between the second interlayer dielectric layer IL2 and the third interlayer dielectric layer IL3. The ground line GNL may intersect, and be connected to, the first wiring line IT(1) and the second wiring line IT(2).

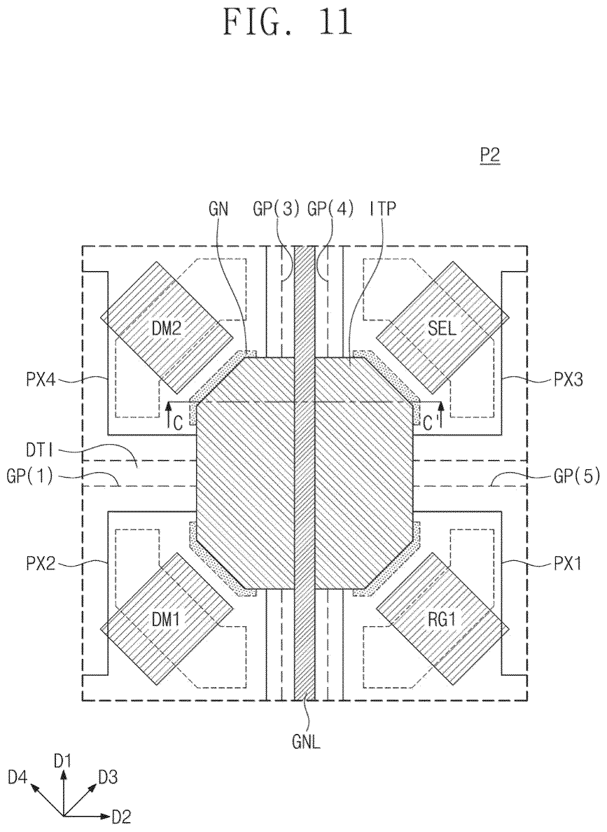

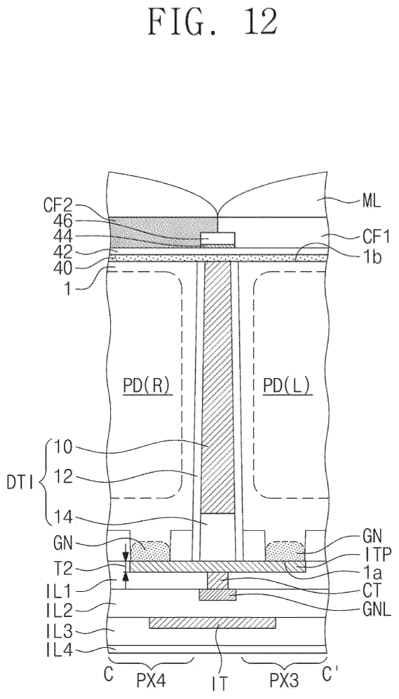

FIG. 11 illustrates an enlarged view showing section P2 of FIG. 6. FIG. 12 illustrates a cross-sectional view taken along line C-C′ of FIG. 11.

Referring to FIGS. 11 and 12, in the image sensor having the pixel arrangement as shown in FIG. 9, a ground pattern ITP may be in contact with four ground regions GN that are adjacent to each other. For example, the ground pattern ITP may be in contact with the ground regions GN of the first, third, fourth, and fifth pixel groups GP(1), GP(3), GP(4), and GP(5). The ground pattern ITP may have an octagonal shape when viewed in plan. Embodiments, however, are not limited thereto, and the ground pattern ITP may have a square or circular shape. The ground pattern ITP may be formed of the same material having the same thickness as that of the first logic gate electrode AT1 depicted in FIG. 2A. The ground pattern ITP and the first logic gate electrode AT1 may be formed of impurity-doped polysilicon. The first logic gate electrode AT1 may have a first thickness T1, and the ground pattern ITP may have a second thickness T2. The second thickness T2 may be about 0.9 times to about 1.1 times the first thickness T1. The ground pattern ITP and the first logic gate electrode AT1 may be located at the same height and may be covered with the first interlayer dielectric layer IL1. Other configurations may be identical or similar to those discussed with reference to FIGS. 9 and 10.

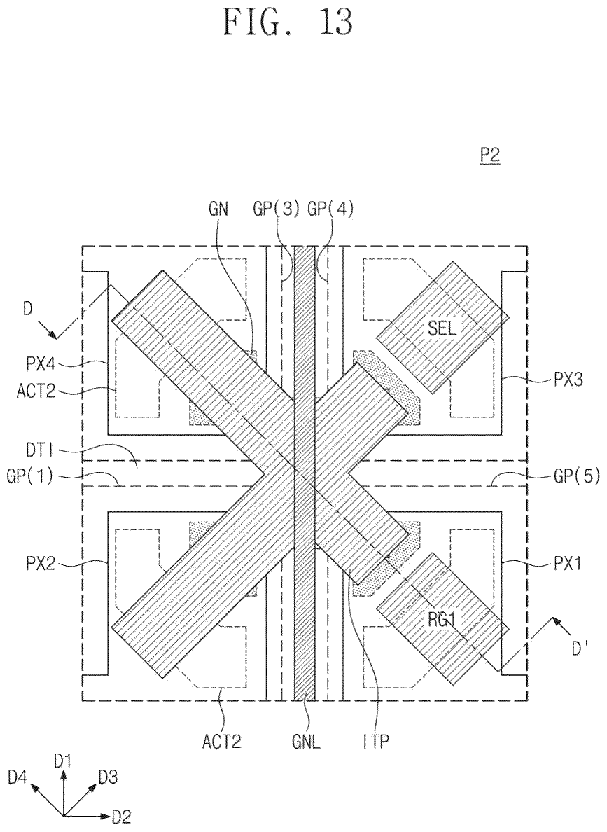

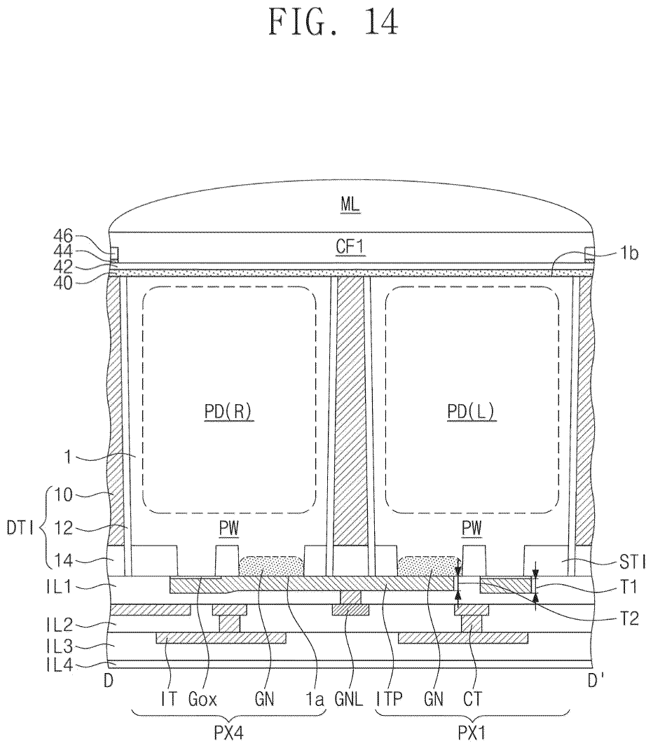

FIG. 13 illustrates an enlarged view showing section P2 of FIG. 6. FIG. 14 illustrates a cross-sectional view taken along line D-D′ of FIG. 13.

Referring to FIGS. 13 and 14, in the image sensor having the pixel arrangement as shown in FIG. 9, the ground pattern ITP may be in contact with four ground regions GN that are adjacent to each other. For example, the ground pattern ITP may be in contact with the ground regions GN of the first, third, fourth, and fifth pixel groups GP(1), GP(3), GP(4), and GP(5). The ground pattern ITP may have an “X” shape when viewed in plan. The ground pattern ITP may extend in the fourth direction D4 to extend across the second active region ACT2 of the fourth pixel PX4 in the third pixel group GP(3). The gate dielectric layer Gox may be interposed between the second active region ACT2 and the ground pattern ITP. The ground pattern ITP on the second active region ACT2 may correspond to the second dummy gate electrode DM2 of FIG. 9. The ground pattern ITP may extend in a direction opposite to the third direction D3 to extend across the second active region ACT2 of the second pixel PX2 in the first pixel group GP(1). The gate dielectric layer Gox may be interposed between the second active region ACT2 and the ground pattern ITP. The ground pattern ITP on the second active region ACT2 may correspond to the first dummy gate electrode DM1 of FIG. 9. Other configurations may be identical or similar to those discussed above.

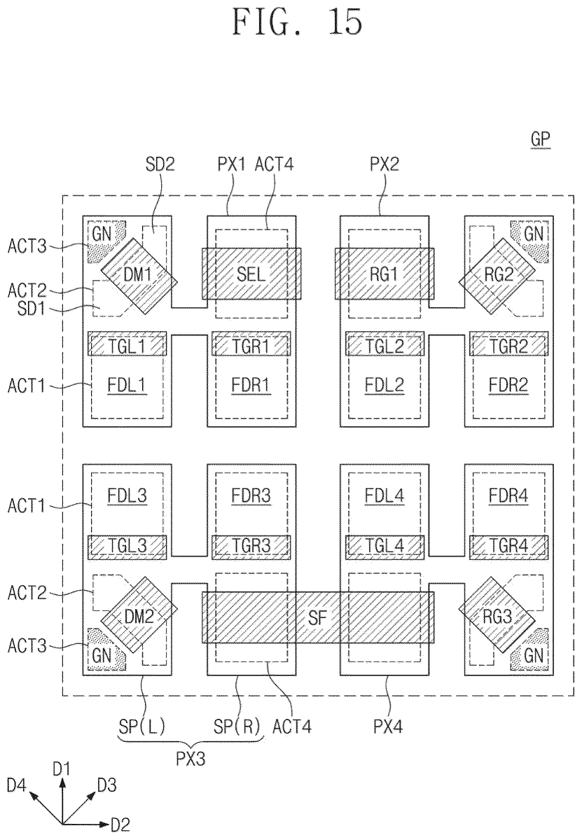

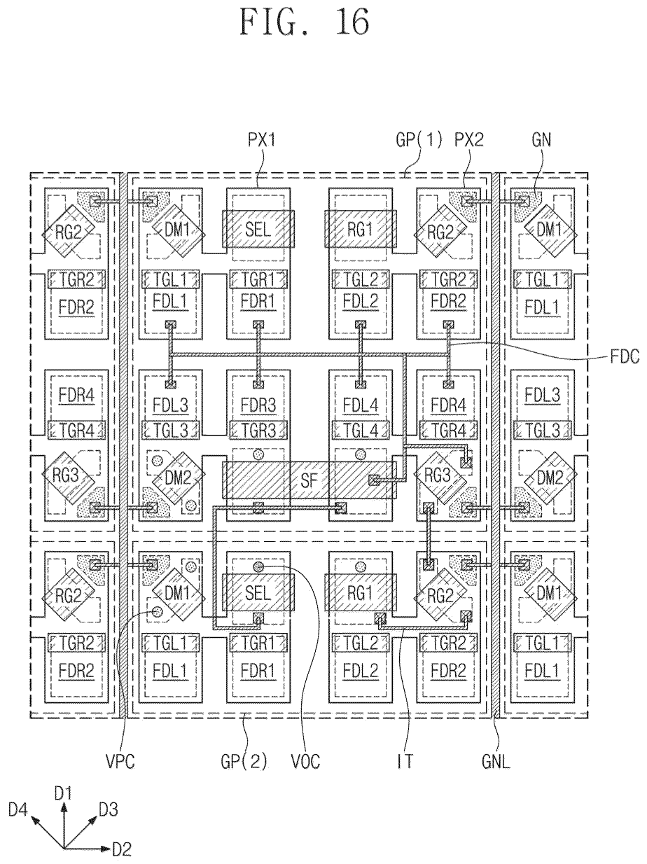

FIG. 15 illustrates a plan view showing one pixel group in an image sensor according to some embodiments. FIG. 16 illustrates a plan view showing a connection relationship between transistors and an arrangement of a pixel group of FIG. 15. A circuit diagram of an image sensor shown in FIG. 16 may be the same as that of FIG. 8.

Referring to FIG. 15, one pixel group GP may include first to fourth pixels PX1 to PX4 disposed in a 2×2 arrangement. On the left sub-pixel SP(L) of the first pixel PX1, the first dummy gate electrode DM1 may extend in the fourth direction D4 across the second active region ACT2. On the right sub-pixel SP(R) of the first pixel PX1, the selection gate electrode SEL may extend in the second direction D2 across the fourth active region ACT4.

On the left sub-pixel SP(L) of the second pixel PX2, the first reset gate electrode RG1 may extend in the second direction D2 across the fourth active region ACT4. On the right sub-pixel SP(R) of the second pixel PX2, the second reset gate electrode RG2 may extend in the third direction D3 across the second active region ACT2.

On the left sub-pixel SP(L) of the third pixel PX3, the second dummy gate electrode DM2 may extend in the third direction D3 across the second active region ACT2. On the right sub-pixel SP(R) of the fourth pixel PX4, the third reset gate electrode RG3 may extend in the fourth direction D4 across the second active region ACT2. Other configurations may be identical or similar to those discussed above with reference to FIGS. 4 and 5.

Referring to FIG. 16, the pixel group GP of FIG. 15 may be two-dimensionally arranged along the first and second directions D1 and D2. In some embodiments, the pixel groups GP of FIG. 15 may be arranged to achieve mirror-symmetry along the first and second directions D1 and D2.

Referring still to FIG. 16, the pixel groups GP may include a first pixel group GP(1) and a second pixel group GP(2) that are adjacent to each other in the first direction D1. A single FD connection line FDC may create a connection between the floating diffusion regions FDL1 to FDL4 and FDR1 to FDR4 disposed on the first pixel group GP(1), the source follower gate electrode SF, and a source/drain region on one side of the third reset gate electrode RG3. One or more of the wiring lines IT may create a serial connection between the third reset transistors RX3 disposed on the first pixel group GP(1) and the first and second reset transistors RX1 and RX2 disposed on the second pixel group GP(2). Another one of the wiring lines IT may connect terminals of the source follower transistor SFX disposed on the first pixel group GP(1) to a terminal of the selection transistor SLX disposed on the second pixel group GP(2). Other connection structures may be identical or similar to those discussed with reference to FIGS. 5 to 14.

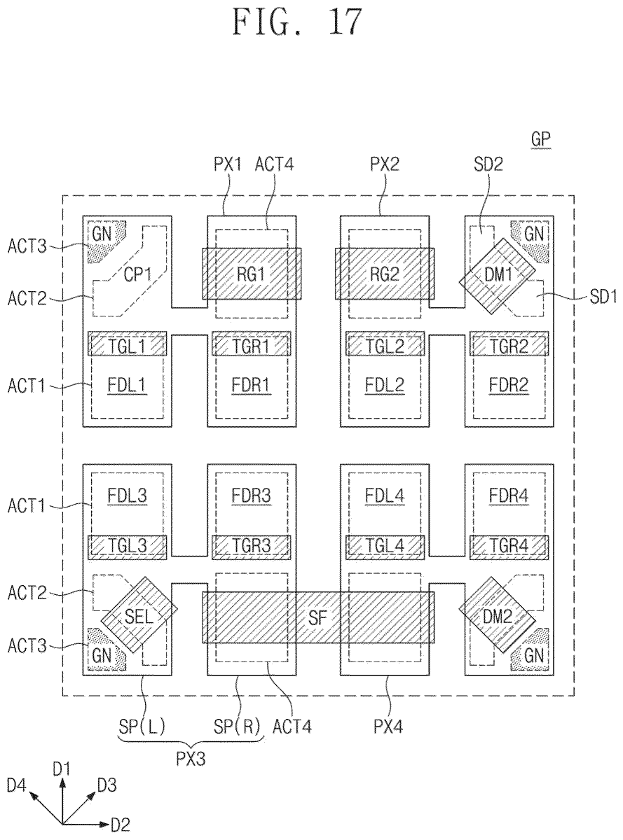

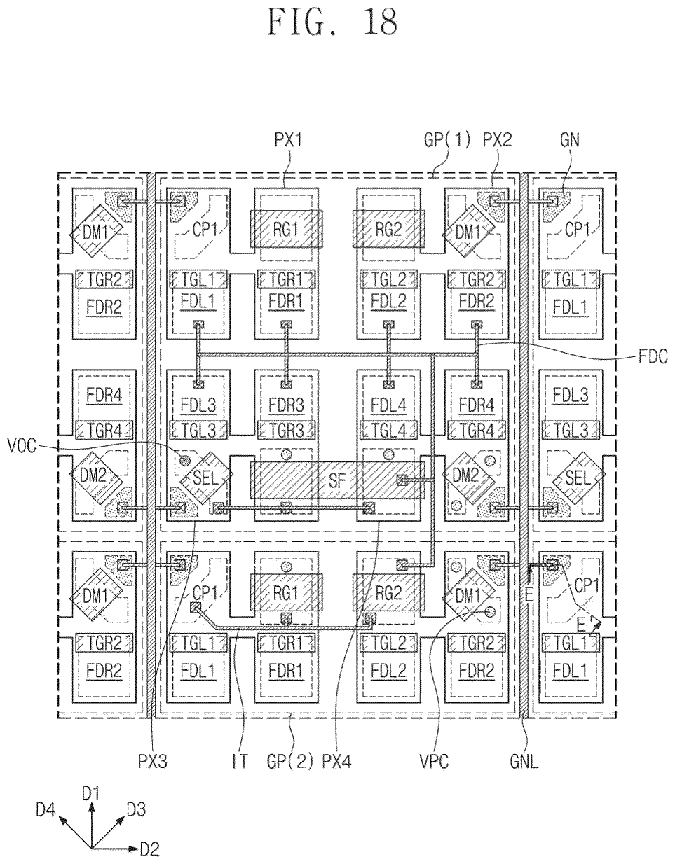

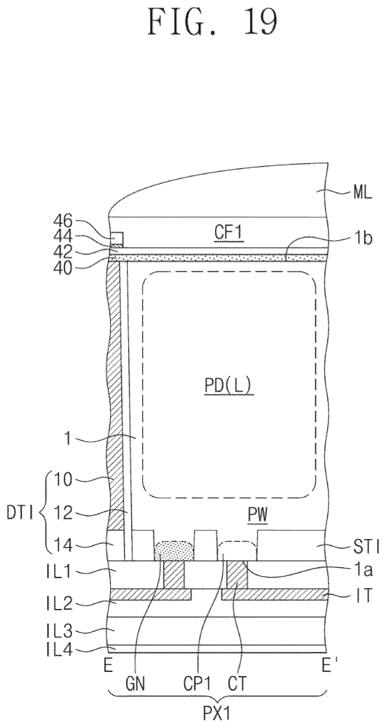

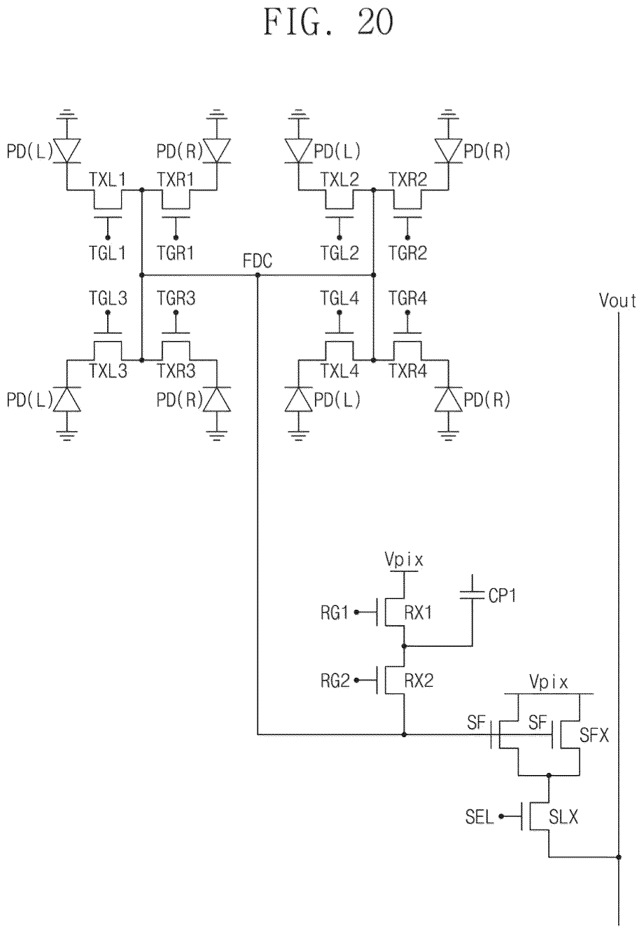

FIG. 17 illustrates a plan view showing one pixel group in an image sensor according to some embodiments. FIG. 18 illustrates a plan view showing a connection relationship between transistors and an arrangement of a pixel group of FIG. 17. FIG. 19 illustrates a cross-sectional view taken along line E-E′ of FIG. 18. FIG. 20 illustrates a circuit diagram of an image sensor shown in FIG. 18.

Referring to FIGS. 17 to 20, one pixel group GP may include first to fourth pixels PX1 to PX4 disposed in a 2×2 arrangement. On the left sub-pixel SP(L) of the first pixel PX1, a first capacitor region CP1 may be disposed on the second active region ACT2. Referring to FIGS. 18 and 19, the first capacitor region CP1 may be doped with impurities having the second conductivity type opposite to the first conductivity type of the impurities doped in the well region PW. The first capacitor region CP1 may be a junction capacitor. On the right sub-pixel SP(R) of the first pixel PX1, the first reset gate electrode RG1 may extend in the second direction D2 across the fourth active region ACT4.

On the left sub-pixel SP(L) of the second pixel PX2, the second reset gate electrode RG2 may extend in the second direction D2 across the fourth active region ACT4. On the right sub-pixel SP(R) of the second pixel PX2, the first dummy gate electrode DM1 may extend in the third direction D3 across the second active region ACT2.

On the left sub-pixel SP(L) of the third pixel PX3, the selection gate electrode SEL may extend in the third direction D3 across the second active region ACT2. On the right sub-pixel SP(R) of the fourth pixel PX4, the second dummy gate electrode DM2 may extend in the fourth direction D4 across the second active region ACT2. One pixel group GP may include two reset transistors RX1 and RX2 and exclude the third reset transistor RX3. Other configurations may be identical or similar to those discussed above with reference to FIGS. 4 and 5.

Referring to FIG. 18, the pixel group GP of FIG. 17 may be two-dimensionally arranged along the first and second directions D1 and D2. In some embodiments, the pixel groups GP of FIG. 17 may be arranged to achieve mirror-symmetry along the first and second directions D1 and D2.

Referring still to FIG. 18, the pixel groups GP may include a first pixel group GP(1) and a second pixel group GP(2) that are adjacent to each other in the first direction D1. A single PD connection line FDC may create a connection between the floating diffusion regions FDL1 to FDL4 and FDR1 to FDR4 disposed on the first pixel group GP(1), the source follower gate electrode SF, and a source/drain region on one side of the second reset gate electrode RG2 disposed on the second pixel group GP(2). One or more of the wiring lines IT may create a serial connection between the first capacitor region CP1 and the first and second reset transistors RX1 and RX2 disposed on the second pixel group GP(2). Another one of the wiring lines IT may connect terminals of the source follower transistor SFX disposed on the first pixel group GP(1) to a terminal of the selection transistor SLX disposed on the first pixel group GP(1). Other connection structures may be identical or similar to those discussed with reference to FIGS. 5 to 14.

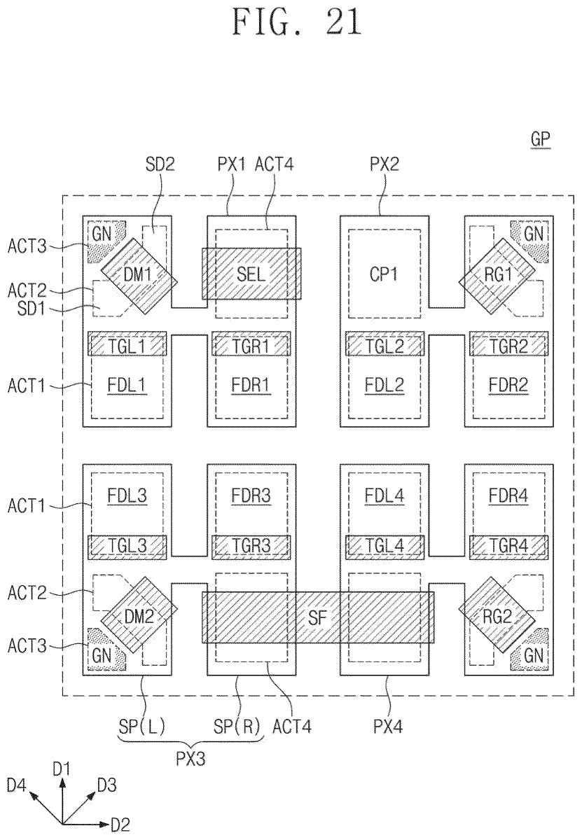

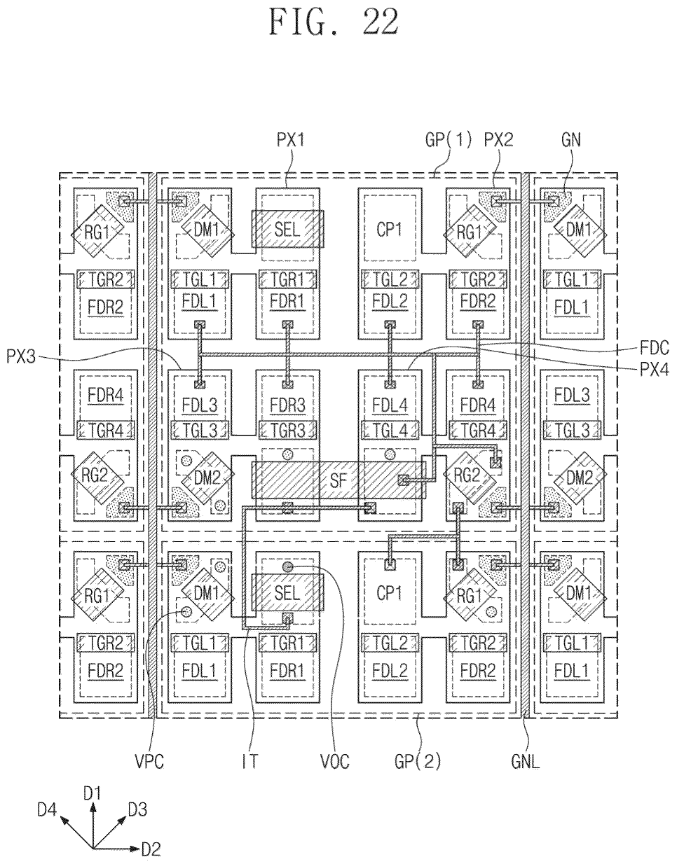

FIG. 21 illustrates a plan view showing one pixel group in an image sensor according to some embodiments. FIG. 22 illustrates a plan view showing a connection relationship between transistors and an arrangement of a pixel group of FIG. 21. A circuit diagram of an image sensor shown in FIG. 22 may be the same as that of FIG. 20.

Referring to FIGS. 21 and 22, one pixel group GP may include first to fourth pixels PX1 to PX4 disposed in a 2×2 arrangement. On the left sub-pixel SP(L) of the first pixel PX1, the first dummy gate electrode DM1 may extend in the fourth direction D4 across the second active region ACT2. On the right sub-pixel SP(R) of the first pixel PX1, the selection gate electrode SEL may extend in the second direction D2 across the fourth active region ACT4.

On the left sub-pixel SP(L) of the second pixel PX2, a first capacitor region CP1 may be disposed on the fourth active region ACT4. The first capacitor region CP1 may be a junction capacitor. On the right sub-pixel SP(R) of the second pixel PX2, the first reset gate electrode RG1 may extend in the third direction D3 across the second active region ACT2.

On the left sub-pixel SP(L) of the third pixel PX3, the second dummy gate electrode DM2 may extend in the third direction D3 across the second active region ACT2. On the right sub-pixel SP(R) of the fourth pixel PX4, the second reset gate electrode RG2 may extend in the fourth direction D4 across the second active region ACT2. Other configurations may be the same as or similar to those discussed with reference to FIG. 17.

Referring to FIG. 22, the pixel group GP of FIG. 21 may be two-dimensionally arranged along the first and second directions D1 and D2. In some embodiments, the pixel groups GP of FIG. 21 may be arranged to achieve mirror-symmetry along the first and second directions D1 and D2.

Referring still to FIG. 22, the pixel groups GP may include a first pixel group GP(1) and a second pixel group GP(2) that are adjacent to each other in the first direction D1. A single FD connection line FDC may create a connection between the floating diffusion regions FDL1 to FDL4 and FDR1 to FDR4 disposed on the first pixel group GP(1), the source follower gate electrode SF, and a source/drain region on one side of the second reset gate electrode RG2. One or more of the wiring lines IT may create a serial connection between the second reset transistors RX2 disposed on the first pixel group GP(1), the first reset transistor RX1 disposed on the second pixel group GP(2), and the first capacitor region CP1. Another one of the wiring lines IT may connect terminals of the source follower transistor SFX disposed on the first pixel group GP(1) to a terminal of the selection transistor SLX disposed on the second pixel group GP(2). Other connection structures may be identical or similar to those discussed with reference to FIGS. 17 to 20.

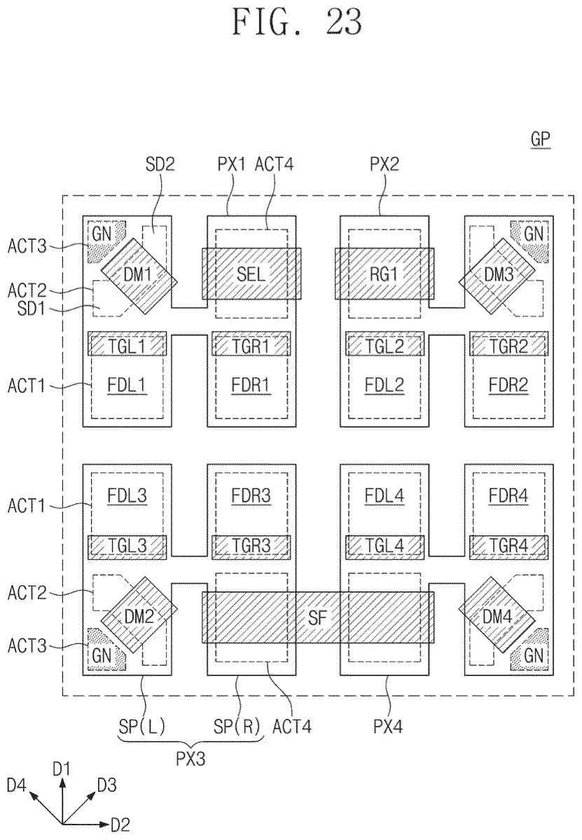

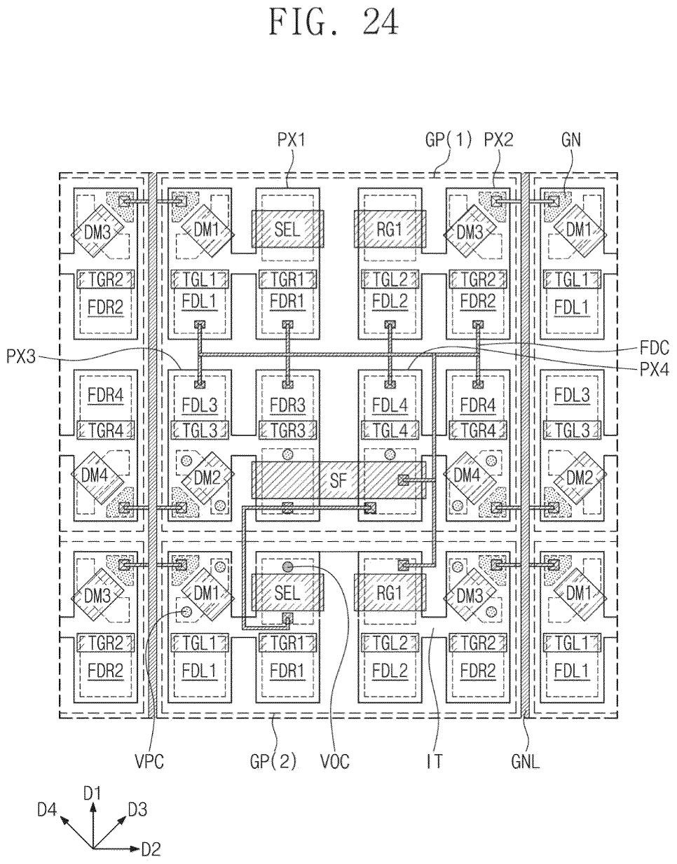

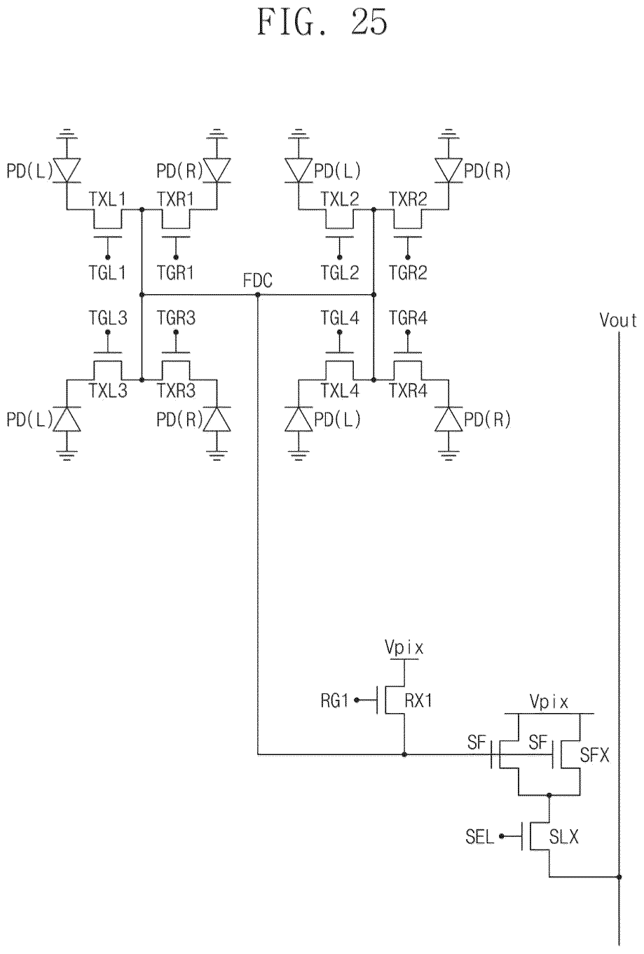

FIG. 23 illustrates a plan view showing one pixel group in an image sensor according to some embodiments. FIG. 24 illustrates a plan view showing a connection relationship between transistors and an arrangement of a pixel group of FIG. 23. FIG. 25 illustrates a circuit diagram of an image sensor shown in FIG. 24.

Referring to FIGS. 23 to 25, one pixel group GP may include first to fourth pixels PX1 to PX4 disposed in a 2×2 arrangement. On the left sub-pixel SP(L) of the first pixel PX1, the first dummy gate electrode DM1 may extend in the fourth direction D4 across the second active region ACT2. On the right sub-pixel SP(R) of the first pixel PX1, the selection gate electrode SEL may extend in the second direction D2 across the fourth active region ACT4.

On the left sub-pixel SP(L) of the second pixel PX2, the first reset gate electrode RG1 may extend in the second direction D2 across the fourth active region ACT4. On the right sub-pixel SP(R) of the second pixel PX2, the third dummy gate electrode DM3 may extend in the third direction D3 across the second active region ACT2.

On the left sub-pixel SP(L) of the third pixel PX3, the second dummy gate electrode DM2 may extend in the third direction D3 across the second active region ACT2. On the right sub-pixel SP(R) of the fourth pixel PX4, the fourth dummy gate electrode DM4 may extend in the fourth direction D4 across the second active region ACT2. One pixel group GP may include one reset transistor RX1 and exclude the second and third reset transistors RX2 and RX3. One pixel group GP may include four dummy transistors. Other configurations may be identical or similar to those discussed above with reference to FIGS. 21 and 22.

Referring to FIG. 24, the pixel group GP of FIG. 23 may be two-dimensionally arranged along the first and second directions D1 and D2. In some embodiments, the pixel groups GP of FIG. 23 may be arranged to achieve mirror-symmetry along the first and second directions D1 and D2.

Referring to FIGS. 24 and 25, the pixel groups GP may include a first pixel group GP(1) and a second pixel group GP(2) that are adjacent to each other in the first direction D1. A single FD connection line FDC may create a connection between the floating diffusion regions FDL1 to FDL4 and FDR1 to FDR4 disposed on the first pixel group GP(1), the source follower gate electrode SF, and a source/drain region on one side of the first reset gate electrode RG1 disposed on the second pixel group GP(2). One of the wiring lines IT may connect terminals of the source follower transistor SFX disposed on the first pixel group GP(1) to a terminal of the selection transistor SLX disposed on the second pixel group GP(2). Other connection structures may be identical or similar to those discussed above with reference to FIG. 22.

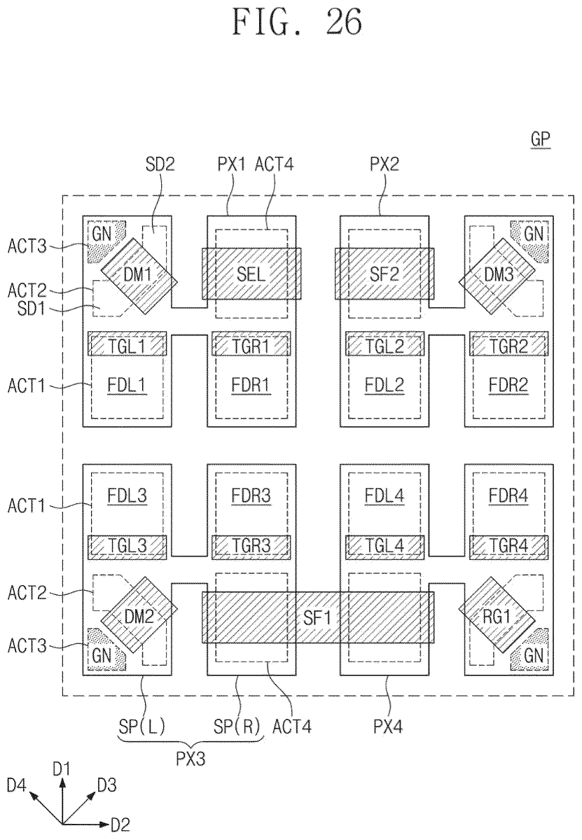

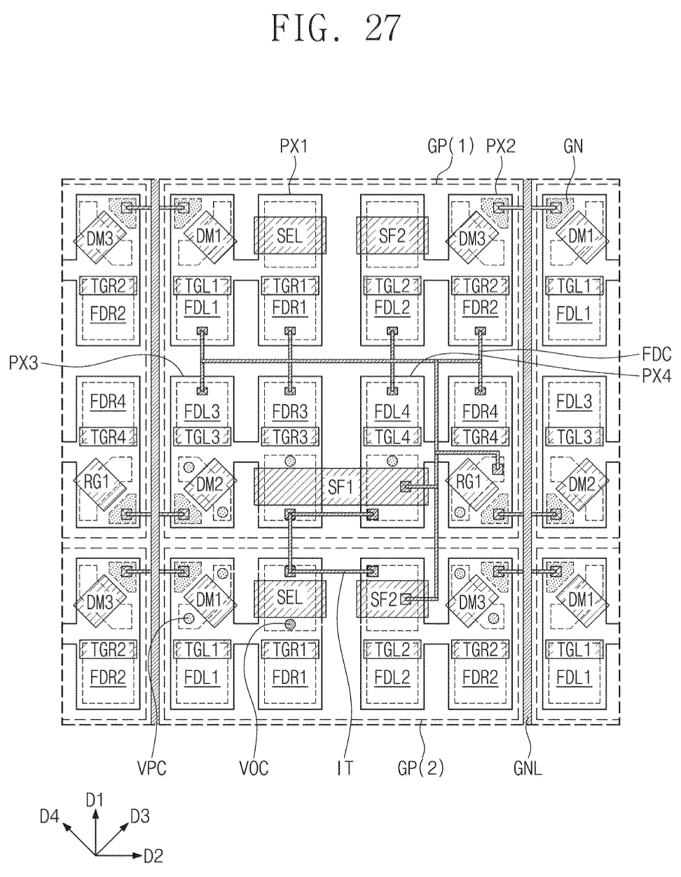

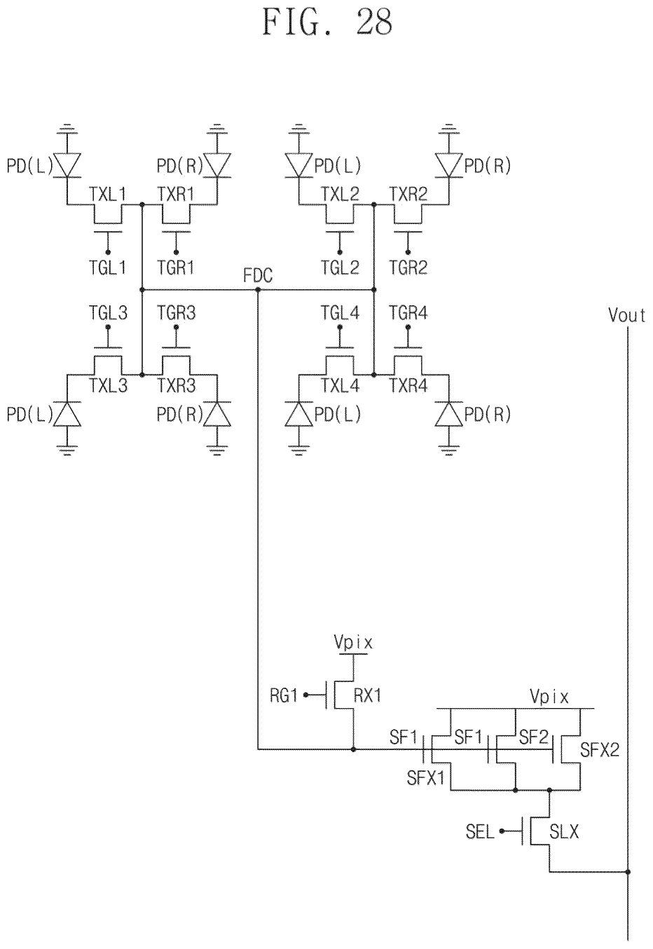

FIG. 26 illustrates a plan view showing one pixel group in an image sensor according to some embodiments. FIG. 27 illustrates a plan view showing a connection relationship between transistors and an arrangement of a pixel group of FIG. 26. FIG. 28 illustrates a circuit diagram of an image sensor shown in FIG. 27.

Referring to FIGS. 26 to 28, one pixel group GP may include first to fourth pixels PX1 to PX4 disposed in a 2×2 arrangement. On the left sub-pixel SP(L) of the first pixel PX1, the first dummy gate electrode DM1 may extend in the fourth direction D4 across the second active region ACT2. On the right sub-pixel SP(R) of the first pixel PX1, the selection gate electrode SEL may extend in the second direction D2 across the fourth active region ACT4.

On the left sub-pixel SP(L) of the second pixel PX2, a second source follower gate electrode SF2 may extend in the second direction D2 across the fourth active region ACT4. The second source follower gate electrode SF2, and first and second source/drain regions SD1 and SD2 on opposite sides thereof, may constitute a second source follower transistor SFX2 of FIG. 28. On the right sub-pixel SP(R) of the second pixel PX2, the third dummy gate electrode DM3 may extend in the third direction D3 across the second active region ACT2.

On the left sub-pixel SP(L) of the third pixel PX3, the second dummy gate electrode DM2 may extend in the third direction D3 across the second active region ACT2. A first source follower gate electrode SF1 may extend in the second direction D2 to extend across the fourth active region ACT4 of the right sub-pixel SP(R) in the third pixel PX3 and the fourth active region ACT4 of the left sub-pixel SP(L) in the fourth pixel PX4. The first source follower gate electrode SF1, and first and second source/drain regions SD1 and SD2 on opposite sides thereof, may constitute a first source follower transistor SFX1 of FIG. 28. The first source follower gate electrode SF1 may have a width greater than that of the second source follower gate electrode SF2.

On the right sub-pixel SP(R) of the fourth pixel PX4, the first reset gate electrode RG1 may extend in the fourth direction D4 across the second active region ACT2. One pixel group GP may include the first source follower transistor SFX1 and the second source follower transistor SFX2. One pixel group GP may include three dummy transistors. Other configurations may be identical or similar to those discussed with reference to FIGS. 23 to 25.

Referring to FIGS. 27 and 28, a plurality of pixel groups GP of FIG. 25 may be two-dimensionally arranged along the first and second directions D1 and D2. In some embodiments, the pixel groups GP of FIG. 25 may be arranged to achieve mirror-symmetry along the first and second directions D1 and D2.

Referring still to FIGS. 27 and 28, the pixel groups GP may include a first pixel group GP(1) and a second pixel group GP(2) that are adjacent to each other in the first direction D1. A single FD connection line FDC may create a connection between the floating diffusion regions FDL1 to FDL4 and FDR1 to FDR4 disposed on the first pixel group GP(1), a source/drain region on one side of the first reset gate electrode RG1, the first source follower gate electrode SF1, and the second source follower gate electrode SF2 disposed on the second pixel group GP(2). One of the wiring lines IT may connect terminals of the first source follower transistor SFX1 disposed on the first pixel group GP(1) to a terminal of the selection transistor SLX disposed on the second pixel group GP(2) and to a terminal of the second source follower transistor SFX2 disposed on the second pixel group GP(2). Other connection structures may be identical or similar to those discussed above with reference to FIG. 24. The first source follower transistor SFX1 and the second source follower transistor SFX2 may be connected in parallel.

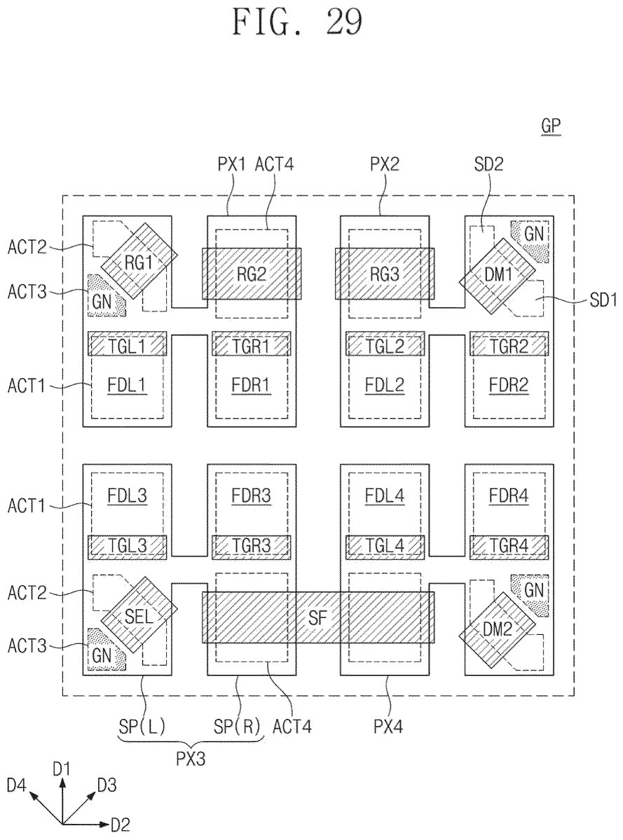

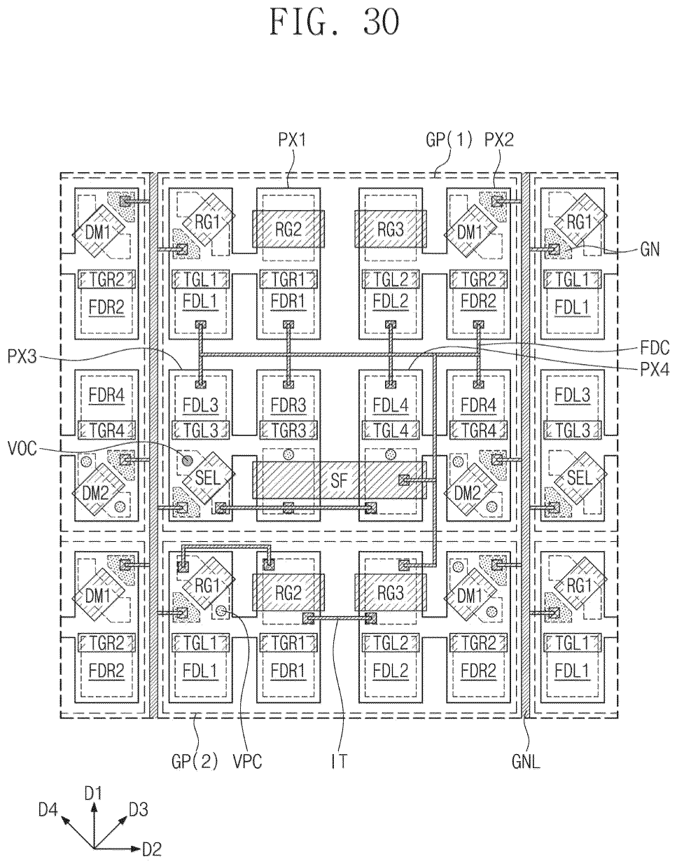

FIG. 29 illustrates a plan view showing one pixel group in an image sensor according to some embodiments. FIG. 30 illustrates a plan view showing a connection relationship between transistors and an arrangement of a pixel group of FIG. 29. A circuit diagram of an image sensor shown in FIG. 30 may be the same as that of FIG. 8.

Referring to FIGS. 29 and 30, an arrangement of transistors on one pixel group GP may be the same as that of FIG. 5. On the first pixel PX1 and the fourth pixel PX4, a position of the second active region ACT2 may interchange with that of the third active region ACT3 on which the ground region GN is disposed. On the first pixel PX1, the first active region ACT1, the third active region ACT3, and the second active region ACT2 may be sequentially disposed along the first direction D1. On the fourth pixel PX4, the first active region ACT1, the third active region ACT3, and the second active region ACT2 may be sequentially disposed in a direction opposite to the first direction D1. On the first pixel PX1 and the fourth pixel PX4, the second active region ACT2 may be elongated along the fourth direction D4.

Referring to FIG. 30, a plurality of pixel groups GP of FIG. 29 may be two-dimensionally arranged along the first and second directions D1 and D2. In some embodiments, the pixel groups GP of FIG. 29 may be arranged to achieve mirror-symmetry along the first and second directions D1 and D2.

Referring to FIGS. 29 and 30, a connection relationship between transistors may be the same as that discussed with reference to FIG. 7. The wiring lines IT which connect the ground regions GN to the ground line GNL may be disposed alternately left and right in a zigzag fashion along the first direction D1. Other structural features may be identical or similar to those discussed above.

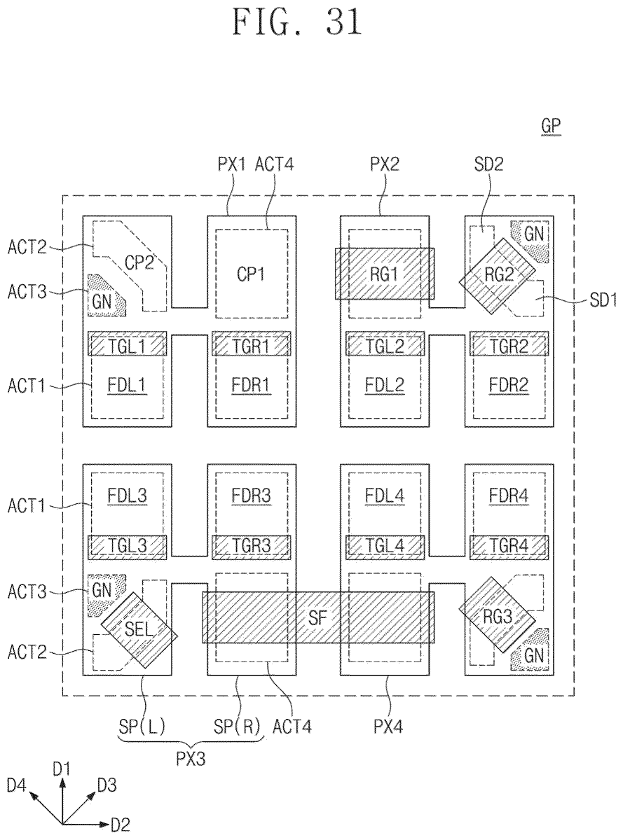

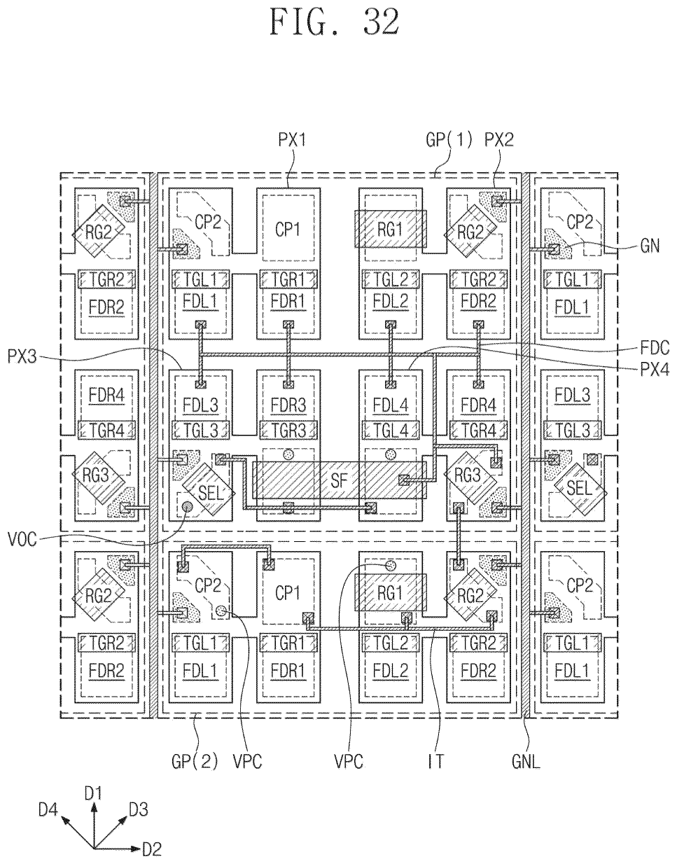

FIG. 31 illustrates a plan view showing one pixel group in an image sensor according to some embodiments. FIG. 32 illustrates a plan view showing a connection relationship between transistors and an arrangement of a pixel group of FIG. 31. A circuit diagram of an image sensor shown in FIG. 30 may be similar to that of FIG. 8.

Referring to FIGS. 31 and 32, one pixel group GP may include first to fourth pixels PX1 to PX4 disposed in a 2×2 arrangement. On the left sub-pixel SP(L) of the first pixel PX1, the first active region ACT1, the third active region ACT3, and the second active region ACT2 may be sequentially disposed along the first direction D1. On the first pixel PX1, the second active region ACT2 may be elongated along the fourth direction D4. On the first pixel PX1, a second capacitor region CP2 may be disposed on the second active region ACT2. On the first pixel PX1, a first capacitor region CP1 may be disposed on the fourth active region ACT4. The first capacitor region CP1 and the second capacitor region CP2 may be junction capacitors.

On the left sub-pixel SP(L) of the second pixel PX2, the first reset gate electrode RG1 may extend in the second direction D2 across the fourth active region ACT4. On the right sub-pixel SP(R) of the second pixel PX2, the second reset gate electrode RG2 may extend in the third direction D3 across the second active region ACT2.

On the left sub-pixel SP(L) of the third pixel PX3, the first active region ACT1, the third active region ACT3, and the second active region ACT2 may be sequentially disposed along a direction opposite to the first direction D1. The selection gate electrode SEL may extend in the fourth direction D4 across the second active region ACT2. On the right sub-pixel SP(R) of the fourth pixel PX4, the third reset gate electrode RG3 may extend in the fourth direction D4 across the second active region ACT2. One pixel group GP may include three reset transistors RX1, RX2, and RX3 and two junction capacitors, but exclude dummy transistors. Other configurations may be identical or similar to those discussed above.

Referring to FIG. 32, a plurality of pixel groups GP of FIG. 31 may be two-dimensionally arranged along the first and second directions D1 and D2. In some embodiments, the pixel groups GP of FIG. 31 may be arranged to achieve mirror-symmetry along the first and second directions D1 and D2.

Referring still to FIG. 32, the pixel groups GP may include a first pixel group GP(1) and a second pixel group GP(2) that are adjacent to each other in the first direction D1. A single FD connection line FDC may create a connection between the floating diffusion regions FDL1 to FDL4 and FDR1 to FDR4 disposed on the first pixel group GP(1), the source follower gate electrode SF, and a source/drain region on one side of the third reset gate electrode RG3. One or more of the wiring lines IT may connect a terminal of the third reset transistor RX3 disposed on the first pixel group GP(1) to terminals of the first and second reset transistors RX1 and RX2 disposed on the second pixel group GP(2) and to the first and second capacitor regions CP1 and CP2. Another one of the wiring lines IT may connect terminals of the source follower transistor SFX disposed on the first pixel group GP(1) to a terminal of the selection transistor SLX disposed on the first pixel group GP(1).

The wiring lines IT which connect the ground regions GN to the ground line GNL may be disposed alternately left and right in a zigzag fashion along the first direction D1. An interval between neighboring wiring lines IT on a left side of the ground line GNL may be less than that between neighboring wiring lines IT on a right side of the ground line GNL. Other configurations may be identical or similar to those discussed above.

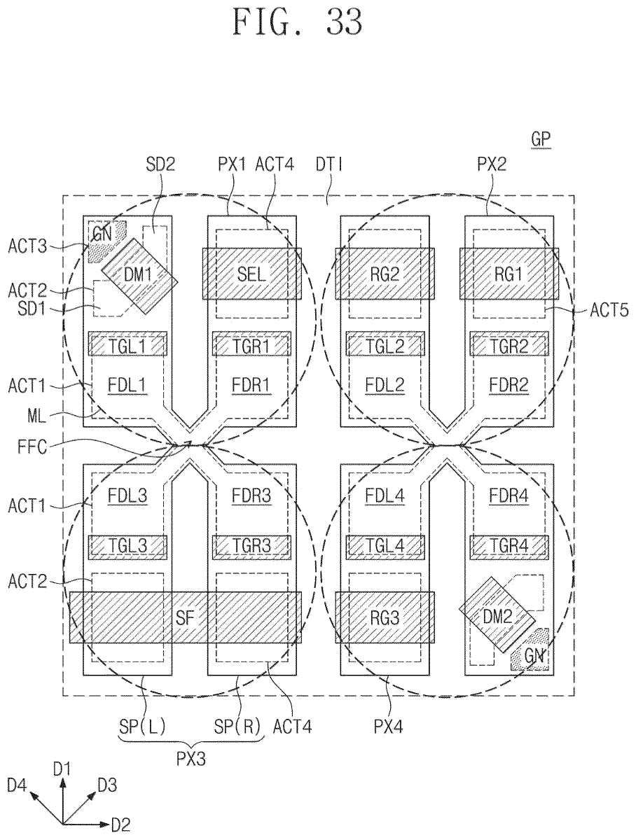

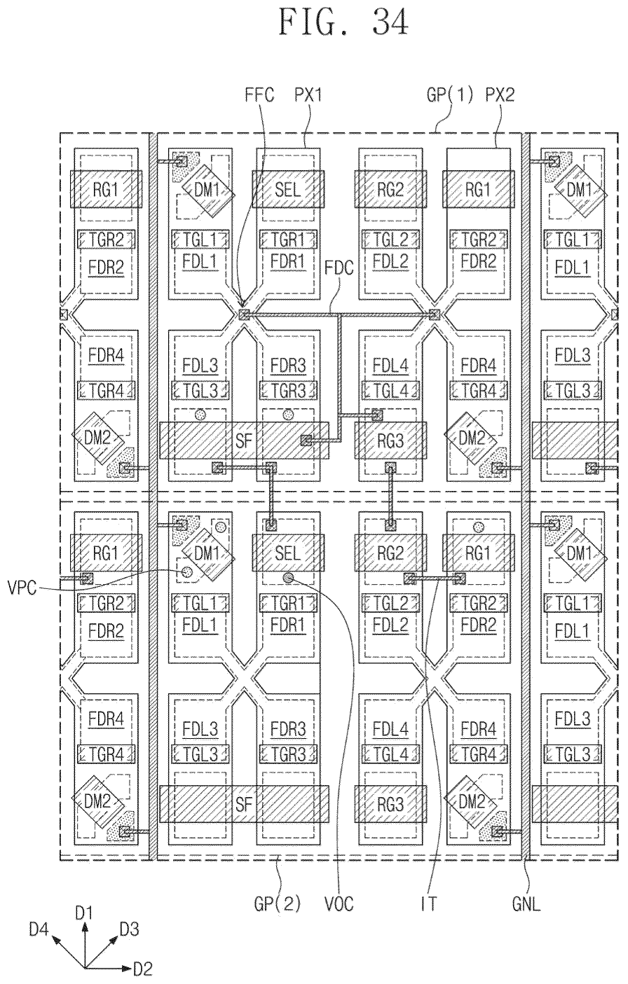

FIG. 33 illustrates a plan view showing one pixel group in an image sensor according to some embodiments. FIG. 34 illustrates a plan view showing a connection relationship between transistors and an arrangement of a pixel group of FIG. 33. A circuit diagram of an image sensor shown in FIG. 34 may be similar to that of FIG. 8.

Referring to FIGS. 2A, 33, and 34, on one pixel group GP in an image sensor, the well regions PW of the first pixel PX1 and the third pixel PX3 may be connected to each other. The pixel separation part DTI may be partially interposed between the first pixel PX1 and the third pixel PX3, but may not completely isolate the first pixel PX1 from the third pixel PX3. A common floating diffusion region FFC may connect the first and third left floating diffusion regions FDL1 and FDL3 to the first and third right floating diffusion regions FDR1 and FDR3. The ground region GN may be disposed on only one of the first pixel PX1 and the third pixel PX3. The ground region GN may be disposed on the first pixel PX1.

On the pixel group GP, the well regions PW of the second pixel PX2 and the fourth pixel PX4 may be connected to each other. The pixel separation part DTI may be partially interposed between the second pixel PX2 and the fourth pixel PX4, but may not completely isolate the second pixel PX2 from the fourth pixel PX4. A common floating diffusion region FFC may extend through the pixel separation part DTI and connect the second and fourth left floating diffusion regions FDL2 and FDL4 to the second and fourth right floating diffusion regions FDR2 and FDR4. The ground region GN may be disposed on only one of the second pixel PX2 and the fourth pixel PX4. The ground region GN may be disposed on the fourth pixel PX4. The right sub-pixel SP(R) of the second pixel PX2 may include the fifth active region ACT5 instead of including any of the second and third active regions ACT2 and ACT3. When viewed in plan, the fifth active region ACT5 may have the same shape as that of the fourth active region ACT4. On each of the first to fourth pixels PX1 to PX4, the pixel separation part DTI may extend across a central portion between the left sub-pixel SP(L) and the right sub-pixel SP(R).

Referring to FIG. 34, a plurality of pixel groups GP of FIG. 33 may be two-dimensionally arranged along the first and second directions D1 and D2. In some embodiments, the pixel groups GP of FIG. 33 may be arranged to achieve mirror-symmetry along the first and second directions D1 and D2.

Referring still to FIG. 34, the pixel groups GP may include a first pixel group GP(1) and a second pixel group GP(2) that are adjacent to each other in the first direction D1. A single FD connection line FDC may create a connection between common floating diffusion regions FFC disposed on the first pixel group GP(1), the source follower gate electrode SF, and a source/drain region on one side of the third reset gate electrode RG3. One or more of the wiring lines IT may connect a terminal of the third reset transistor RX3 disposed on the first pixel group GP(1) to terminals of the first and second reset transistors RX1 and RX2 disposed on the second pixel group GP(2). Another one of the wiring lines IT may connect terminals of the source follower transistor SFX disposed on the first pixel group GP(1) to a terminal of the selection transistor SLX disposed on the second pixel group GP(2).

The wiring lines IT which connect the ground regions GN to the ground line GNL may be disposed alternately left and right in a zigzag fashion along the first direction D1. Other configurations may be identical or similar to those discussed above.

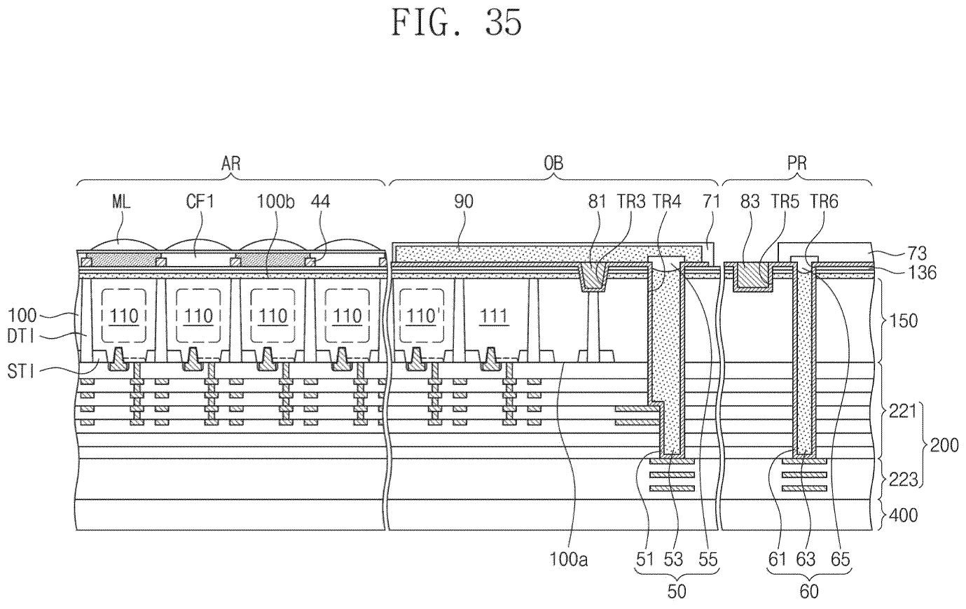

FIG. 35 illustrates a cross-sectional view showing an image sensor according to some embodiments.

Referring to FIG. 35, an image sensor according to some embodiments may include a substrate 100 including a pixel array area AR, an optical black area OB, and a pad area PAD, and may also include a wiring layer 200 on a first surface 100a of the substrate 100 and a base substrate 400 on the wiring layer 200. The wiring layer 200 may include an upper wiring layer 221 and a lower wiring layer 223. The pixel array area AR may include a plurality of pixels PX. The pixels PX disposed on the pixel array area AR may be substantially the same as that discussed above with reference to FIGS. 1 to 34.

On the optical black area OB, the substrate 100 may be provided thereon with a first connection structure 50, a first conductive pad 81, and a bulk color filter 90. The first connection structure 50 may include a first light-shield pattern 51, a dielectric pattern 53, and a first capping pattern 55.

The first light-shield pattern 51 may be disposed on a second surface 100b of the substrate 100. For example, the first light-shield pattern 51 may conformally covering an inner wall of a third trench TR3 and an inner wall of a fourth trench TR4, while covering a second dielectric layer 136 on the second surface 100b. The first light-shield pattern 51 may penetrate a photoelectric conversion layer 150 and the upper wiring layer 221 to connect the photoelectric conversion layer 150 to the wiring layer 200. For example, the first light-shield pattern 51 may be in contact with wiring lines in the upper and lower wiring layers 221 and 223 and with a separation conductive pattern 10 of a pixel separation part DTI in the photoelectric conversion layer 150. Therefore, the first connection structure 50 may be electrically connected to wiring lines in the wiring layer 200. The first light-shield pattern 51 may include a metallic material, such as tungsten. The first light-shield pattern 51 may block incidence of light into the optical black area OB.

The first conductive pad 81 may be provided in the third trench TR3 to fill an unoccupied portion of the third trench TR3. The first conductive pad 81 may include a metallic material, such as aluminum. The first conductive pad 81 may be connected to the separation conductive pattern 10 of FIG. 2A. A negative bias voltage may be applied through the first conductive pad 81 to the separation conductive pattern 10. Therefore, it may be possible to prevent or reduce white spot and/or dark current.

The dielectric pattern 53 may fill an unoccupied portion of the fourth trench TR4. The dielectric pattern 53 may completely or partially penetrate the photoelectric conversion layer 150 and the wiring layer 200. The first capping pattern 55 may be provided on a top surface of the dielectric pattern 53. The first capping pattern 55 may be provided on the dielectric pattern 53.

The bulk color filter 90 may be provided on the first conductive pad 81, the first light-shield pattern 51, and the first capping pattern 55. The bulk color filter 90 may cover the first conductive pad 81, the first light-shield pattern 51, and the first capping pattern 55. A first protection layer 71 may be provided on and encapsulate the bulk color filter 90. The first protection layer 71 may be formed of a transparent dielectric material.

A photoelectric conversion region 110′ and a dummy region 111 may be provided on the optical black area OB of the substrate 100. The photoelectric conversion region 110′ may be doped with impurities, for example, having the second conductivity type different from the first conductivity type. The second conductivity type may be, for example, of n-type. The pixel array area AR may include a plurality of pixels PX. The photoelectric conversion region 110′ may have a similar structure to that of a photoelectric conversion region 110 on the pixel array area AR, but may not perform an operation (e.g., generation of electrical signals from incident light) the same as that of the photoelectric conversion region 110. The dummy region 111 may not be doped with impurities. The dummy region 111 may generate signals that are used as information to remove subsequent process noise.

On the pad area PAD, the substrate 100 may be provided thereon with a second connection structure 60, a second conductive pad 83, and a second protection layer 73. The second connection structure 60 may include a second light-shield pattern 61, a dielectric pattern 63, and a second capping pattern 65.

The second light-shield pattern 61 may be disposed on the second surface 100b of the substrate 100. For example, the second light-shield pattern 61 may conformally cover an inner wall of a fifth trench TR5 and an inner wall of a sixth trench TR6, while covering the second dielectric layer 136 on the second surface 100b. The second light-shield pattern 61 may penetrate the photoelectric conversion layer 150 and the upper wiring layer 221 to connect the photoelectric conversion layer 150 to the wiring layer 200. For example, the second light-shield pattern 61 may be in contact with wiring lines in the lower wiring layer 223. Therefore, the second connection structure 60 may be electrically connected to wiring lines in the wiring layer 200. The second light-shield pattern 61 may include a metallic material, such as tungsten.

The second conductive pad 83 may be provided in the fifth trench TR5 to fill an unoccupied portion of the fifth trench TR5. The second conductive pad 83 may include a metallic material, such as aluminum. The second conductive pad 83 may serve as an electrical connection path through which the image sensor is connected to an external apparatus. The dielectric pattern 63 may fill an unoccupied portion of the sixth trench TR6. The dielectric pattern 63 may completely or partially penetrate the photoelectric conversion layer 150 and the wiring layer 200. The second capping pattern 65 may be provided on the dielectric pattern 63. The second protection layer 73 may cover the second capping pattern 65 and a portion of the second light-shield pattern 61.

A current applied through the second conductive pad 83 may flow through the second light-shield pattern 61, the wiring lines in the wiring layer 200, and the first light-shield pattern 51 to the separation conductive pattern 10 of the pixel separation part DTI. The photoelectric conversion regions 110 and 110′ and the dummy region 111 may generate electrical signals, and the electrical signals may be outwardly transmitted through the wiring lines in the wiring layer 200, the second light-shield pattern 61, and the second conductive pad 83.

An image sensor according to some embodiments may be configured such that, on one pixel including two sub-pixels, a ground region may be disposed on a corner portion of the pixel. As no ground region is disposed on a cutting region of a pixel separation part, it may be possible to reduce a gate width of a logic transistor adjacent thereto. Therefore, a random telegram signal (RTS) may be improved, and the image sensor may achieve sharp image quality. In addition, as no ground region is disposed on the cutting region, an autofocus (AF) segregation ratio may increase to perform an excellent autofocus function.

While aspects of embodiments have been particularly shown and described, it will be understood that various changes in form and details may be made therein without departing from the spirit and scope of the following claims.

1. An image sensor, comprising:
a substrate that comprises a plurality of pixels, each of which comprises a left sub-pixel and a right sub-pixel;
a well region in the substrate on each of the plurality of pixels, the well region connecting the left sub-pixel and the right sub-pixel to each other;
a pixel separation part that separates the plurality of pixels from each other and extends in the substrate between the left sub-pixel and the right sub-pixel;
a left transfer transistor and a first logic transistor on the left sub-pixel;
a right transfer transistor and a second logic transistor on the right sub-pixel; and
a ground region in the substrate on one of the left sub-pixel and the right sub-pixel, and in contact with the well region,
wherein the ground region is adjacent to a corner of each of the plurality of pixels.

2. The image sensor of claim 1, further comprising a microlens on the left sub-pixel and the right sub-pixel on each of the plurality of pixels.

3. The image sensor of claim 1, further comprising a device isolation part in the substrate on a center of each of the plurality of pixels.

4. The image sensor of claim 1, wherein the left transfer transistor is spaced apart in a first direction from the first logic transistor,
wherein the right transfer transistor is spaced apart in the first direction from the second logic transistor,
wherein the ground region is adjacent in a second direction to the first logic transistor, the second direction intersecting the first direction,
wherein a gate electrode of the first logic transistor is elongated in the second direction, and
wherein a gate electrode of the second logic transistor is elongated in a third direction that intersects the first direction and the second direction.

5. The image sensor of claim 1, further comprising a device isolation part in the substrate,
wherein the device isolation part separates active regions of the left transfer transistor, the right transfer transistor, the first logic transistor, the second logic transistor, and the ground region, and
wherein a portion of a gate electrode of one of the first logic transistor and the second logic transistor extends into the device isolation part and covers a lateral surface of the substrate.

6. The image sensor of claim 1, wherein each of gate electrodes of the left transfer transistor and the right transfer transistor comprises at least one protruding part that extends into the substrate.

7. An image sensor, comprising:
a substrate comprising a plurality of pixel groups, each of which comprises a plurality of pixels in a 2×2 arrangement, each of the plurality of pixels comprising a left sub-pixel and a right sub-pixel;
a well region in the substrate on each of the plurality of pixels, the well region connecting the left sub-pixel and the right sub-pixel to each other;
a pixel separation part that separates the plurality of pixels from each other and extends in the substrate between the left sub-pixel and the right sub-pixel;
a left transfer transistor and a left active region on the left sub-pixel;
a right transfer transistor and a right active region on the right sub-pixel;
a ground region in the substrate on one of the left sub-pixel and the right sub-pixel, and in contact with the well region; and
a ground line that extends over the substrate between the plurality of pixel groups,
wherein, on each of the plurality of pixels, the ground region is adjacent to the ground line.

8. The image sensor of claim 7, further comprising:
a microlens on the left sub-pixel and the right sub-pixel of each of the plurality of pixels;
a first color filter on one of the plurality of pixel groups;
a second color filter on another of the plurality of pixel groups; and
a third color filter on still another of the plurality of pixel groups.

9. The image sensor of claim 7, wherein the left transfer transistor is spaced apart in a first direction from the left active region,
wherein the right transfer transistor is spaced apart in the first direction from the right active region, and
wherein the ground line extends in the first direction.

10. The image sensor of claim 7, wherein each of the plurality of pixel groups comprises a first pixel, a second pixel, a third pixel, and a fourth pixel,
wherein the first pixel and the second pixel are side by side in a first direction to constitute a first row,
wherein the third pixel and the fourth pixel are side by side in the first direction to constitute a second row, and
wherein the left transfer transistor and the right transfer transistor on the first pixel and the second pixel, are adjacent to the left transfer transistor and the right transfer transistor on the third pixel and the fourth pixel.

11. The image sensor of claim 10, further comprising:
a first reset gate electrode that extends over the left active region of the first pixel;
a second reset gate electrode that extends over the right active region of the first pixel;
a third reset gate electrode that extends over the left active region of the second pixel;
a first dummy gate electrode that extends over the right active region of the second pixel;
a selection gate electrode that extends over the left active region of the third pixel;
a source follower gate electrode that extends over the right active region of the third pixel and the left active region of the fourth pixel; and
a second dummy gate that extends over the right active region of the fourth pixel.

12. The image sensor of claim 11, wherein one of the first reset gate electrode, the second reset gate electrode, and the third reset gate electrode has a first width in the first direction,
wherein the source follower gate electrode has a second width in the first direction, and
wherein the second width is greater than the first width.

13. The image sensor of claim 10, wherein the plurality of pixel groups comprise a first pixel group, a second pixel group, a third pixel group, and a fourth pixel group in a 2×2 arrangement,
wherein the ground line is between the first pixel group and the second pixel group, and between the third pixel group and the fourth pixel group,
wherein the ground region comprises a plurality of first ground regions on the fourth pixel of the first pixel group, the third pixel of the second pixel group, the second pixel of the third pixel group, and the first pixel of the fourth pixel group, and
wherein the plurality of first ground regions are adjacent to the ground line.

14. The image sensor of claim 13, wherein the plurality of first ground regions are spaced apart at a common distance from the ground line.

15. The image sensor of claim 13, further comprising:
a first interlayer dielectric layer on the substrate;
a plurality of first ground contacts that extend into the first interlayer dielectric layer to correspondingly contact the plurality of first ground regions;
a first wiring line on the first interlayer dielectric layer to connect the plurality of first ground contacts to each other; and
a second interlayer dielectric layer on the first wiring line,
wherein the ground line is on the second interlayer dielectric layer and connected to the first wiring line.

16. The image sensor of claim 13, further comprising a ground pattern on the substrate and in contact with the plurality of first ground regions,
wherein the ground line extends over the ground pattern.

17. The image sensor of claim 16, wherein the ground pattern has an octagonal shape or a cross shape when viewed in plan.

18. The image sensor of claim 16, further comprising a first reset gate electrode on the left active region of one of the plurality of pixels,
wherein the ground pattern and the first reset gate electrode have a common thickness.

19. The image sensor of claim 16, wherein a portion of the ground pattern extends over the right active region of the fourth pixel of the first pixel group and over the right active region of the second pixel of the third pixel group, and
wherein the image sensor further comprises a gate dielectric layer between the ground pattern and the right active region.

20-26. (canceled)

27. An image sensor, comprising:
a substrate having a first surface and a second surface that are opposite to each other, the substrate comprising a plurality of pixel groups, each of which comprises a plurality of pixels arranged in a 2×2 matrix, and each of the plurality of pixels comprising a left sub-pixel and a right sub-pixel;
a first color filter on the first surface covering one of the plurality of pixel groups;
a second color filter on the first surface covering another of the plurality of pixel groups;
a third color filter on the first surface covering still another of the plurality of pixel groups;
a plurality of microlenses respectively provided on the first color filter, the second color filter, and the third color filter and covering each of the plurality of pixels;
a well region in the substrate on each of the plurality of pixels, the well region connecting the left sub-pixel and the right sub-pixel to each other;
a pixel separation part that separates the plurality of pixels from each other and extends between the left sub-pixel and the right sub-pixel;
a device isolation part adjacent to the second surface in the substrate, the device isolation part separating a left active region on the left sub-pixel from a right active region on the right sub-pixel;
a left photoelectric conversion region in the substrate on the left sub-pixel of each of the plurality of pixels;
a right photoelectric conversion region in the substrate on the right sub-pixel of each of the plurality of pixels;
a left transfer transistor on the second surface on each of the plurality of pixels;
a right transfer transistor on the second surface on each of the plurality of pixels; and
a ground region in the substrate on one of the left sub-pixel and the right sub-pixel and in contact with the well region,
wherein the ground region is provided in plural, and
wherein the plurality of ground regions are adjacent to a corner of each of the plurality of pixel groups.
